(19) United States
(12) Patent Application Publication
(10) Pub. No.: US 2009/0278178 A1
(43) Pub. Date: Nov. 12, 2009

(54) SEMICONDUCTOR DEVICE AND METHOD FOR FABRICATING THE SAME

(75) Inventors: Jun Kawahara, Tokyo (JP); Hironori Yamamoto, Tokyo (JP); Makoto Ueki, Tokyo (JP); Yoshihiro Hayashi, Tokyo (JP)

Correspondence Address: NEC CORPORATION OF AMERICA, 6535 N. STATE HWY 161, IRVING, TX, 75039, US

(73) Assignee: NEC CORPORATION, MINATION-KU TOKYO (JP)

(21) Appl. No.: 12/445,996

(22) PCT Filed: Oct. 16, 2008
(86) PCT No.: PCT/JP2008/068719

§ 371 Date: Apr. 17, 2009

(30) Foreign Application Priority Data
Dec. 12, 2006 (DE) 10-2006-058-956.4

(51) Int. Cl. H01L 29/51; H01L 21/768; H01L 23/48; H01L 21/28

(52) U.S. Cl. 257/288; 438/637; 257/774; 438/585; 438/689; 438/666; 257/E21.19; 257/E21.577; 257/E21.585; 257/E23.011; 257/E29.162

(57) ABSTRACT

Disclosed is a semiconductor device which includes a MIS FET on a surface of a substrate, an insulating film on the substrate to cover the MIS FET, an opening that gets to an impurity diffusing region formed in the insulating film, another opening that gets to a gate electrode or to an extension part of the gate electrode formed in the insulating film, and an electrically conductive member including mainly copper filled in each of the openings. The insulating film includes a layer including, as main components, silicon, oxygen, carbon and hydrogen (FIG. 1).

The application is the National Phase of PCT/JP2008/068719, filed Oct. 16, 2008 and claims priority rights based on the Japanese Patent Application 2007-270517, filed in Japan on Oct. 17, 2007, and on the Japanese Patent Application 2008-091749, filed in Japan on Mar. 31, 2008. The total disclosures of these Patent Applications of the senior filing dates are to be incorporated herein by reference.

### TECHNICAL FIELD

1. Reference to Related Application

This invention relates to a semiconductor device and a method for fabricating the same. More particularly, it relates to a semiconductor device having a contact layer structure in which, in case of using copper as a contact plug electrically interconnecting a diffusion layer or a gate electrode of a transistor and an overlying conductor layer, a low dielectric constant film with a dielectric constant not higher than 3.5 is used as an interlayer insulating layer, and a method for fabricating the same.

2. Background Art

In the field of manufacture of integrated circuits for electronics, there is an increasing demand for higher integration density and higher operating speed. In silicon ULSIs, in particular, logic LSIs performing high speed operations or analog-digital mixed LSIs for high frequency, it is contemplated to improve the performance by the miniaturization of MOSFET. In such case, performance limitations by parasitic components around periphery of a transistor are presenting serious problems. In short, it is now incumbent to reduce the resistances of conductive layers of a gate electrode and conductive layers of source and drain sections, other than a channel part, of a transistor, and contact plugs connected thereto, and capacitances between respective conductor sections.

In light of the above, expectations are being made for introducing contact plugs of copper in lieu of those of tungsten which are currently used in many semiconductor integrated circuits, because copper is lower in electrical resistance than tungsten. Reports have already been made of a process including forming a barrier metal layer after boring a contact hole, forming a plating seed layer, and performing copper plating.

An insulating film layer, in which a contact plug is formed, the silicate glass, such as BPSG or PSG, or a silicon dioxide film (SiO₂), formed by plasma chemical vapor deposition (chemical vapor deposition is herein after abbreviated to CVD), has so far been used. In the plasma CVD, tetraethoxysilane (TEOS) is used as a raw material. As regards the material of the insulating film layer, it has been proposed to use a low dielectric constant material with the dielectric constant k equal to 3.5 or less.

In Patent Document 1 (JP Patent Kokai JP-A-2007-73663), with regard to a structure in which a copper contact plug is used and formed in a low dielectric constant film, as the insulating film layer, there is proposed a method including depositing a SiOC film, which is a film of carbon-containing silicon oxide, as an interlayer dielectric film, and filling copper on top of the gate electrode to form an electrical conductor. Patent Document 2 (JP Patent Kokai JP-A-2005-175252) shows a method including forming an interlayer dielectric film of a low-k material on top of a transistor region and filling Cu in a contact hole via a barrier metal layer to form interconnects. In these related art techniques, it is stated that the interlayer dielectric film, in which the contact plug is formed, is formed of a low dielectric constant material.

### Patent Document 1:

JP Patent Kokai Publication No. JP2007-73663A

### Patent Document 2:

JP Patent Kokai Publication No. JP2005-175252A

### SUMMARY

The following analysis of the related arts is given by the present invention. In the techniques of Patent Documents 1 and 2, there are the following problems. In case the insulating film of low dielectric constant, that is, a low-k dielectric film, is simply used as an interlayer dielectric film, and in particular, there is a void(s) in the film, when a defect is produced in the course of formation of the barrier metal layer, copper is diffused via these voids through the bulk of the insulating film, thus deteriorating transistor characteristics. Copper is a heavy metal. If such heavy metal is diffused and gets to an impurity diffusion area of a MIS FET, there is formed a deep impurity level in a silicon band gap, thus shortening the life of the carrier or increase of a junction leakage current. Thus, if copper is used for a contact plug in place of tungsten which has so far been used for such purpose, more attention needs to be paid in connection with a method to prevent its diffusion than if tungsten is used.

In view of the above-depicted problems of the related art, it is an object of the present invention to provide a semiconductor device in which, when copper is used as a contact plug, it is possible to prevent copper from being diffused from the contact plug via an insulating film to an impurity diffusion area of the MIS (Metal Insulator Semiconductor) type FET (Field Effect Transistor).

In one aspect of the present invention, there is provided a semiconductor device including: a substrate;

a MIS FET provided on a surface of the substrate;

an insulating film provided on the substrate to cover the MIS FET;

an opening formed in the insulating film, the opening getting to an impurity diffusing region of the MIS FET;

an opening formed in the insulating film, the opening getting to a gate electrode of the MIS FET or to an extension part of the gate electrode; and

an electrically conductive member filled into each of the openings, the electrically conductive member including, as a main component, copper;

the insulating film including a layer comprising mainly silicon, oxygen, carbon and hydrogen.

In another aspect of the present invention, there is provided a method for fabricating a semiconductor device comprising the steps of:

(a) depositing an insulating film including, as main components, silicon, oxygen, carbon and hydrogen, on a substrate on which a MIS FET is provided, so as to cover the MIS FET;
(b) forming, in the insulating film, an opening getting to an impurity diffusing region of the MIS FET and another opening getting to a gate electrode of the MIS FET or an extension part of the gate electrode;
(c) forming a barrier layer and a seed layer in this order on an inner wall of the opening;
(d) filling an electrically conductive member including, as a main component, copper, in each of the openings; and
(e) removing the electrically conductive member on the insulating film so that an upper surface of the insulating film will be flush with an upper surface of the electrically conductive member.

According to the present invention, it is possible to suppress diffusion of copper, used as a contact plug of a semiconductor device, from the contact plug via an insulating film to an impurity diffusion region of a MIS FET.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIGS. 1A and 1B show the structures of a semiconductor device according to an exemplary embodiment of the present invention.

FIG. 2 is a cross-sectional view showing another example of the structure of a semiconductor device of the exemplary embodiment of the present invention.

FIGS. 3A and 3B show the structure of a semiconductor device according to the exemplary embodiment and Example 8 of the present invention.

FIGS. 4A to 4E are cross-sectional views for illustrating process steps of a method for fabricating a semiconductor device according to the exemplary embodiment and Example 1 of the present invention.

FIG. 5 is a schematic view of a film forming apparatus used for the method for fabricating a semiconductor device of Example 1 of the present invention.

FIG. 6 shows the results of Raman spectroscopic analysis of a low dielectric constant film of Example 1 of the present invention.

FIG. 7 shows the results of Fourier transform infrared spectroscopic analysis of a low dielectric constant film of Example 1 of the present invention.

FIG. 8 shows elastic modulus of a low dielectric constant film prepared for Example 1 of the present invention.

FIGS. 9A and 9B show resistance against copper diffusion of a low dielectric constant film prepared for Example 1 of the present invention.

FIGS. 10A to 10E show an example of process steps of the method for fabricating a semiconductor device according to Example 2 of the present invention.

FIGS. 11A and 11B show another Example of a semiconductor device according to Example 2 of the present invention.

FIGS. 12A and 12B show another Example of a semiconductor device according to Example 2 of the present invention.

FIGS. 13A to 13E show an example of process steps of the method for fabricating a semiconductor device according to Example 3 of the present invention.

FIGS. 14A to 14E show an example of process steps of the method for fabricating a semiconductor device according to Example 4 of the present invention.

FIGS. 15A to 15E show an example of process steps of the method for fabricating a semiconductor device according to Example 5 of the present invention.

FIGS. 16A to 16E show an example of process steps of the method for fabricating a semiconductor device according to Example 6 of the present invention.

FIG. 17 is a cross-sectional view showing a further example of the semiconductor device according to Example 6 of the present invention.

FIGS. 18A to 18D show an example of process steps of the method for fabricating a semiconductor device according to Example 7 of the present invention.

FIG. 19 shows a further example of the semiconductor device according to Example 7 of the present invention.

FIG. 20 shows a further example of the semiconductor device according to Example 9 of the present invention.

FIGS. 21A to 21C show a semiconductor device according to Example 9 of the present invention.

FIGS. 22A and 22B show an example of a structure of the semiconductor device according to a further exemplary embodiment of the present invention.

FIGS. 23A and 23B show a further example of the structure of a semiconductor device according to the further exemplary embodiment of the present invention.

FIGS. 24A and 24B show a further example of the structure of a semiconductor device according to the further exemplary embodiment of the present invention.

FIGS. 25A to 25D show an example of the process steps of the method for fabricating the semiconductor device according to Example 10 of the present invention.

FIG. 26 is a graph for comparing the relationship between cumulative probability distribution of the junction leakage current of Example 10 of the present invention and a conventional W plug.

FIG. 27 is a graph for comparing the relationship between the contact resistance and the contact diameter of Example 10 of the present invention and a conventional W plug.

FIG. 28 is a graph for comparing the relationship between the junction leakage current and the contact miss alignment of Example 10 of the present invention and a conventional W plug.

FIG. 29 is a graph showing the relationship between the gate voltage and the drain current of the transistor of Example 10 of the present invention.

FIG. 30 is a graph showing the relationship between the on-current and the off-current of the transistor of Example 10 of the present invention and those of the conventional W plug.

FIG. 31 is a graph showing the results of comparison of the NBTI evaluations of the transistor of Example 10 of the present invention and those of the conventional W plug.

FIGS. 32A and 32B are graphs showing the results of comparison of TDDB test results of the transistor of Example 10 of the present invention and those of the conventional W plug.

FIG. 33 shows comparison of the propagation delay time and the power consumption incurred in the operations of a ring oscillator constructed by a transistor of Example 10 of the present invention and a transistor of a conventional W plug.

### PREFERRED MODES

Exemplary embodiments of the present invention will now be described in detail with reference to the drawings.

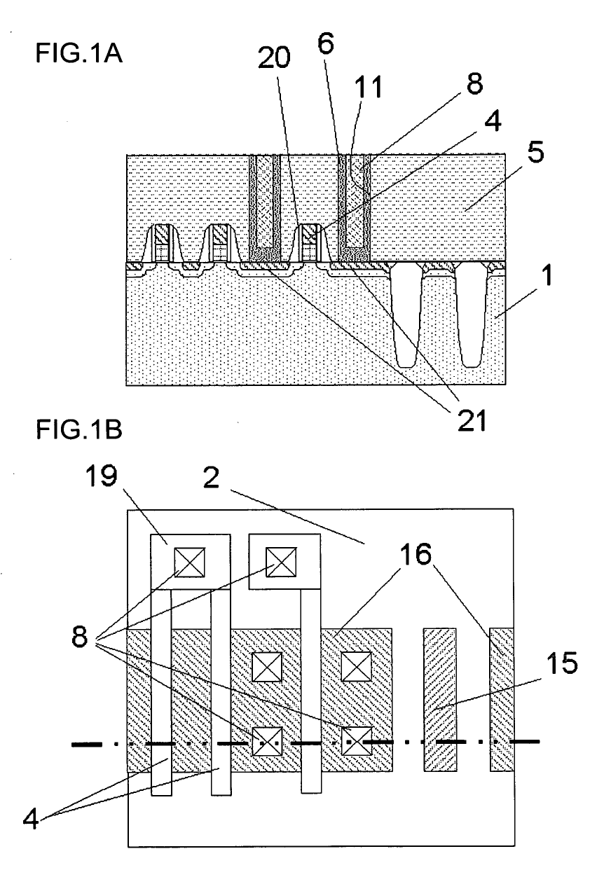

FIGS. 1A and 1B show a configuration of a semiconductor device according to an exemplary embodiment of the present invention. FIG. 1A depicts a cross-sectional view taken along a double-dotted chain line of FIG. 1B. Referring to FIG. 1A, the semiconductor device of the exemplary embodiment of the present invention includes a MIS FET 20 on the surface of a substrate 1. An insulating film 5 is formed to cover the MIS FET 20 on top of the substrate 1. An opening 11 is bored in the insulating film 5 to extend to an impurity diffusing region 21 of the MIS FET 20. An electrically conductive member 8, including as a main component, copper, is filled into the opening 11. The insulating film 5 includes a layer comprising mainly silicon, oxygen, carbon and hydrogen. The insulating film 5 mainly corresponds to an interlayer insulating film. The opening 11 corresponds to a contact hole, and the electrically conductive member 8 corresponds to a contact plug. An opening reaching a gate electrode is not shown in FIG. 1A. As shown in FIG. 1B, an extension part 19 of the gate electrode 4 is provided along depth direction of FIG. 1A. An opening that gets to extension part 19 is provided and the electrically conductive member 8 including, as a main component, copper, is filled in the opening in the same way as the aforementioned opening.

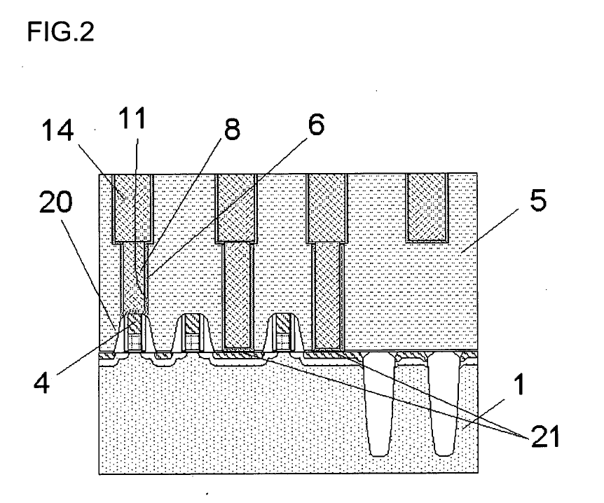

FIG. 2 shows a configuration in case the opening 11 in the semiconductor device of FIG. 1 gets to the impurity diffusing region 21 and to the gate electrode 4 of the MIS FET 20. Here, the opening is formed not via the extension part 19 of the gate electrode 4, but directly on top of the gate electrode 4, thus in a manner different from the case already described with reference to FIG. 1.

It is noted that copper that composes the electrically conductive member 8 may be doped with Al, Ti, Zr, Hf, Co, Sn, Mn, Cr, Ag, Cd or Pd, as a dopant. In order for the electrically conductive member 8 to fulfill its function desired of a contact plug, the doping quantity of these dopants is preferably 1% or less.

The composition ratio of the silicon, oxygen, carbon and hydrogen in the insulating film 5 is preferably on the order of 1.0:1.5:1.0:4.0. The function of the interlayer insulating film may be fulfilled, in case the proportions of oxygen, carbon and hydrogen within about 20% of the above values.

On the surfaces of the impurity diffusing region 21 and the gate electrode 4 is formed a metal silicide which is a compound of a metal, such as tungsten (W), titanium (Ti), cobalt (Co), nickel (Ni) or platinum (Pt), and silicon. The metal silicide may be a compound of a plurality of metals and silicon, such as nickel platinum silicide (NiPtSi).

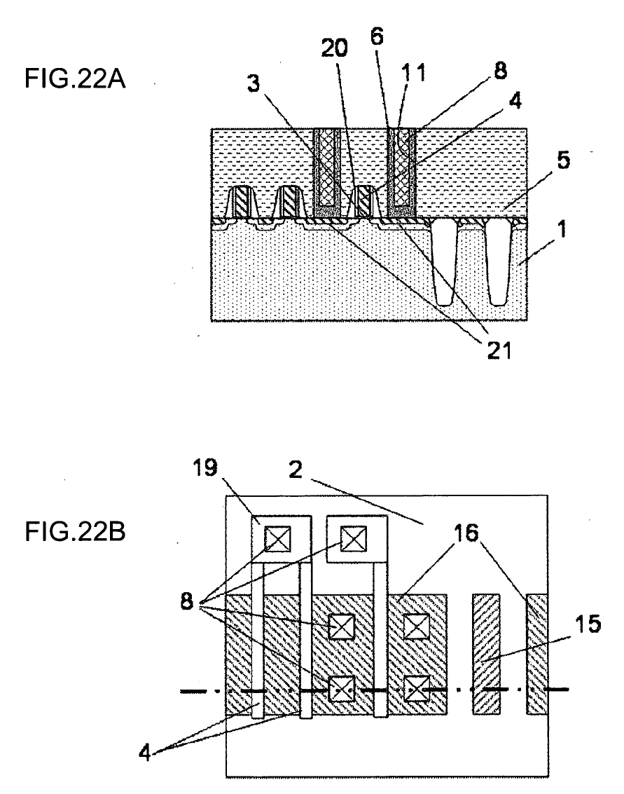

Referring to FIG. 22A, the portion of the gate electrode 4, arranged on a gate insulating film 3, may be metalized in its entirety. FIG. 22B is a top plane view of FIG. 22A. It should be noted that, as regards the transistor, the description of parts other than the gate electrode 4, impurity diffusing region 21 and the contact plug has been omitted. FIG. 22A depicts a cross-sectional view taken along a double-dotted chain line of FIG. 22B. The gate electrode 4, formed of polysilicon in its entirety, may be nickel silicided, or may be replaced in its entirety by a metal(s) or a metal compound(s). The gate electrode may also be of a stacked structure composed of doped polysilicon and a metal(s) or a metal compound(s). The metal compound(s) may be exemplified by a metal carbide(s), a metal silicide(s) and a metal nitride(s). The specific metal(s) may include, for example, Al, Pt, Ta, W, Ru or Re. The metal carbide(s) may include, for example, TaC. The metal silicide(s) and the metal nitride(s) may include, for example, TaSi, HfSi, PtSi, HfSiN, MoSiN, TaSiN, TiSiN, TiCN, MoN, TiN, TaN, HfN or AlN. These materials may also be doped with, for example, Tb, Er or Yb.

The gate insulating film 3 is usually a film of a silicon compound, such as silicon oxide (SiO₂) or silicon oxi-nitride (SiON). To raise the dielectric constant of the gate insulating film, a so-called high-k material, obtained on adding hafnium or aluminum to the above silicon compound, may also be used. Specifically, HfSiON or HfSiO may be used. Or, HfO₂, HfON, HtN, HfAlO, HfAlON, Al₂O₃, HfZrO, HfLaO, ZrO₂, LaYO, La₂O₃, TiO₂, Ta₂O₅, Y₂O₃, AlN or Sc₂O₃, may also be used.

The gate insulating film 3 may include a stacked structure formed of the above materials. The gate insulating film 3 may include a stacked structure including the silicon compound or the above high-k materials, or a multi-layered stacked structure, including the combination of a plurality of the above materials.

The composition ratio of elements of the gate electrode materials and the gate insulating film materials may not necessarily be as indicated above.

In case the above high-k material is used as a material for the gate insulating film 3, the gate electrode 4 preferably may be metal silicided in its entirety, or may be formed of metal or a metal compound in place of polysilicon, as shown in the drawing.

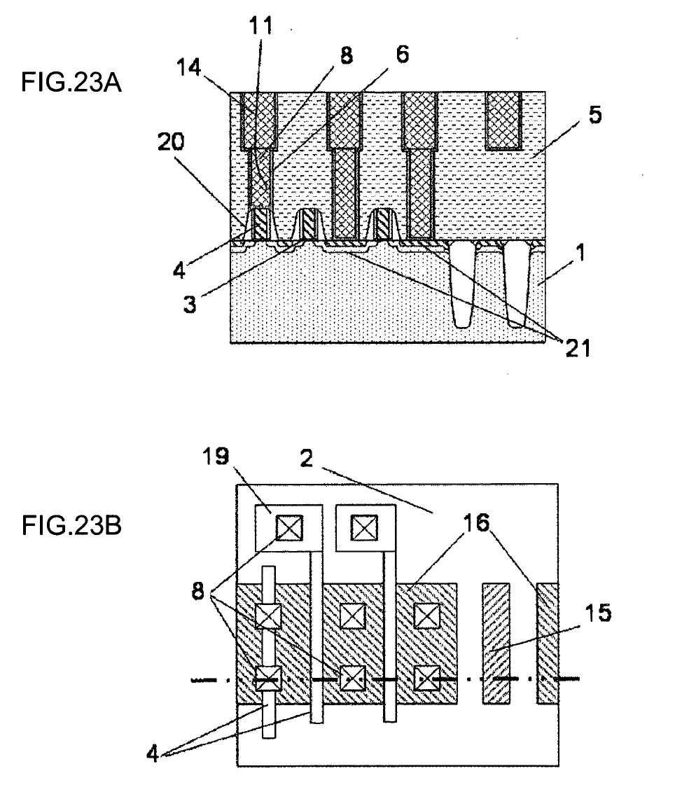

FIG. 23A depicts an arrangement in which, in the semiconductor device of FIG. 22A, the opening 11 gets to the gate electrode 4 and to the impurity diffusing region 21 of the MIS FET 20. It should be noted that, in a manner different from the case shown in FIG. 1, the opening is formed not via the extension part 19 of the gate electrode 4, but directly on top of the gate electrode 4, as shown in FIG. 23B.

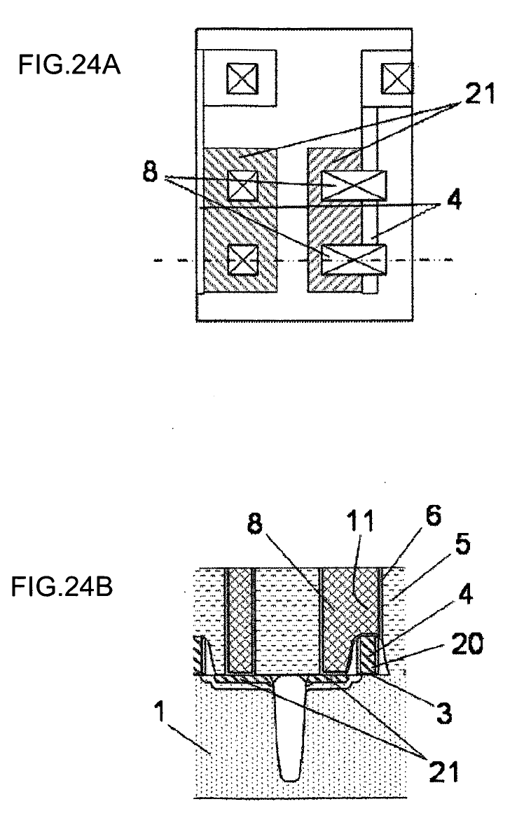

In the semiconductor device of FIG. 22A, the insulating film 5 may be provided with an opening 11 that gets to an area astride the impurity diffusing region 21 and the gate electrode 4 of the MIS FET 20, as shown in FIGS. 24A and 24B.

The insulating film 5 may be of a multi-layer stacked structure having at least one layer including, as main components, silicon, oxygen, carbon and hydrogen. A lowermost layer of the multi-layer stacked structure may include mainly silicon, oxygen, carbon and hydrogen.

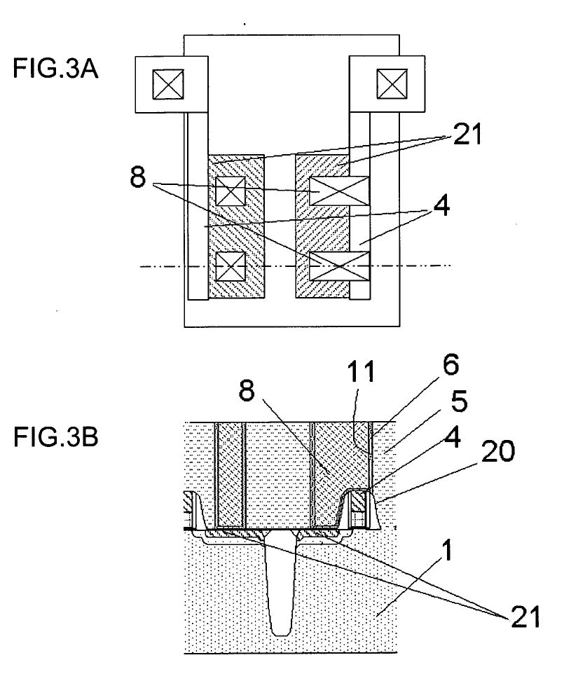

The insulating film 5 may be provided with an opening 11 that gets to an area astride the impurity diffusing region 21 and the gate electrode 4 of the MIS FET 20, as shown in FIGS. 3A and 3B.

The opening 11 may also be configured to extend from a conductor 14 provided within the bulk of the insulating film 5 to the impurity diffusing region 21 and to the gate electrode 4 of the MIS FET 20, as shown in FIG. 2. Although not shown in FIG. 2, the opening 11 may also be constructed so as to extend from the conductor 14 provided within the insulating film 5 to the impurity diffusing region 21 and to the extension part 19 of the gate electrode 4 of the MIS FET 20.

Preferably, a barrier layer 6 is provided on an inner wall of the opening 11. The barrier layer 6 includes a film of an electrically conductive metal having barrier property. The barrier layer 6 is formed to cover lateral side and bottom surface of the conductor to prevent metal element (s) of the conductor or a contact plug from being diffused to the interlayer insulating film or to an underlying layer. For example, if the conductor includes metal element(s) including, as a main component, copper, the barrier layer may include high melting metal(s) or nitride(s) thereof, such as tantalum (Ta), tantalum nitride (TaN), titanium (Ti), titanium nitride (TiN), titanium silicium nitride (TiSiN), wolfram nitride (WN), wolfram carbide nitride (WCN), ruthenium (Ru), zirconium nitride (ZrN), titanium zirconium (TiZr) or copper manganese (CuMn). The barrier layer may also be a stacked film formed of these materials.

The layer including, as main components, silicon, oxygen, carbon and hydrogen preferably contains amorphous carbon and unsaturated hydrocarbons. The amorphous carbon preferably comprises an atom having sp² hybrid orbitals and an atom having sp³ hybrid orbitals, as electron orbitals.

Preferably, the insulating film 5 is provided with a metal wall section extending from the surface of the insulating film 5 to the substrate 1 for surrounding the MIS FET 20. The metal herein means intrinsic metal elements and transition metal elements to the exclusion of so-called metalloid, such as a semiconductor.

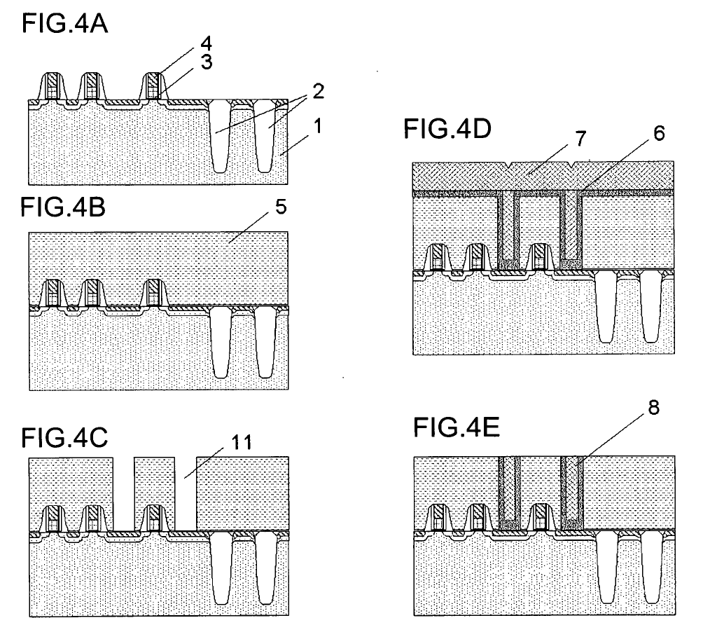

FIGS. 4A-4E show steps of a fabrication method of a semiconductor device according to an exemplary embodiment of the present invention.

FIG. 4A shows a substrate having a structure following the formation of the MIS FET 20 prepared using a typical method for fabrication of an integrated circuit. In FIG. 4A, 1 denotes a substrate, 2 denotes a STI (shallow trench isolation), 3 denotes a gate insulating film and 4 denotes a gate electrode. It is sufficient that the substrate 1 is a substrate on which a MIS FET is formed. Thus, the substrate 1 may not only be a monocrystalline silicon substrate, but may also include a SOI (silicon-on-insulator) substrate or a substrate for fabrication of a TFT (thin film transistor) or liquid crystal.

Referring to FIG. 4B, the insulating film 5, including, as main components, silicon, oxygen, carbon and hydrogen, is deposited on the substrate to cover the MIS FET 20. The insulating film 5 may be deposited using chemical vapor deposition (CVD), sputtering or physical vapor deposition (PVD) as necessary.

The opening 11 is bored to get to the impurity diffusing region 21 of the MIS FET 20, as shown in FIG. 4C. Only the portion of the opening 11 that gets to the impurity diffusing region 21 is shown in the drawing, however, in actuality, the gate electrode extension part 19, which is a part of the gate electrode 4, is formed along a depth-wise direction of the drawing sheet, and another opening 11 is formed to get to the extension part 19 for the gate electrode 4 of the MIS FET 20. The openings 11 may be formed by lithography and etching.

The barrier layer 6 and a seed layer including copper (not shown) are formed in this order on the inner wall of the opening 11. An electrically conductive member 7, including, as a main component, copper, is then filled in the opening 11 by plating, for instance. It is sufficient that the electrically conductive member 7 thus filled in is formed mainly of copper. The electrically conductive member may contain an additive other than copper, such as metal aluminum, to improve the reliability of the copper conductor.

Finally, copper on top of the insulating film 5 is removed by a technique such as chemical mechanical polishing (CMP) so that the upper surface of the insulating film 5 is flush with the upper surface of the electrically conductive member 7 formed of copper. An electrically conductive member 8, filled into the opening 11, is left in the opening. The CMP is a method of polishing and planarizing a wafer surface so as to be free of recesses and protrusions, produced during the process of forming a multi-layer interconnect, by a process of contacting the wafer surface with a rotating abrasive pad as a polishing solution is caused to flow on the wafer surface.

After that, a multi-layer interconnect is then formed to complete the semiconductor integrated circuit.

The insulating film 5 is preferably deposited by plasma chemical vapor deposition (CVD) from a compound represented by the following generalized chemical formula:

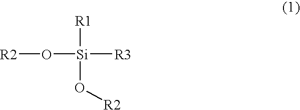

In the above formula (1), R1 denotes chained or branched unsaturated hydrocarbons with 2 to 5 carbon atoms, and R2, R3 denote chained or branched alkyl groups with 1 to 4 carbon atoms. R2 and R3 may be different from or the same as each other.

R1 may include vinyl, propenyl, isopropenyl, 1-methyl-propenyl, 2-methyl-propenyl and 1,2-dimethyl-propenyl groups. R2 and R3 may include methyl, ethyl, propyl, isopropyl, butyl, isobutyl, sec-butyl or tert-butyl groups.

In the raw material, shown in the formula (1), R1 is the sole functional group bonded to silicon. However, if the compound has two or more unsaturated hydrocarbon groups, the raw material itself may undergo self-polymerization or otherwise become labile, thus presenting a problem as regards stability as the film-forming material. Hence, a single unsaturated hydrocarbon group is desirable. Since the straight-chained structure of silicon-oxygen-carbon forms a skeleton of the ultimate film, a plurality of the unsaturated hydrocarbon groups are desirably used in view of film strength. In addition, the hydrocarbon groups, directly bonded to silicon, contribute to reducing the dielectric constant of the film. In light of the above, the numbers of R1, R2 and R3 in the raw material of the formula (1) are desirably one, two and one, respectively.

It is desirable for R1 to possess the function of a polymerization cross-linking group in the course of film forming. It is therefore desirable for an unsaturated hydrocarbon group to be susceptible to reaction. Hence, the vinyl group, simplest in structure among unsaturated hydrocarbons, is most preferred as R1.

As regards R2, it is desirable that a straight-chained structure, made up of silicon, oxygen and carbon, is present in the film. If there are larger numbers of carbon atoms of the alkyl group of R2, the oxygen-carbon bond is liable to be ruptured. Hence, smaller numbers of carbon atoms of the alkyl group of R2 are preferred. For this reason, the methyl group with the smallest number of carbon atoms is preferred.

R3 affects the dielectric constant of the insulating film formed of the raw material represented by the formula (1). Hence, larger numbers of carbon groups are felt to be inherently desirable as the alkyl group of R3, because the film is lower in density with increase in bulkiness of the hydrocarbon groups. However, if the number of carbon atoms is excessive, the silicon-carbon bond is liable to be ruptured during film forming. Moreover, larger numbers of the carbon atoms lead to an increased molecular weight of the raw material to render it difficult to vaporize the raw material as the film-forming material and to transport it in the vapor phase. It is therefore desirable that R3 is an alkyl group with a bulky structure even though the number of carbon atoms is small. Specifically, higher hydrocarbon groups, such as tert-butyl group or isobutyl group, may be desirable. Of these, the isopropyl group, the simplest branched alkyl group, is most desirable.

In light of the above, it is most desirable that the insulating film 5 is formed of isopropyl dimethoxy vinyl siloxane having the composition indicated by the following formula (2):

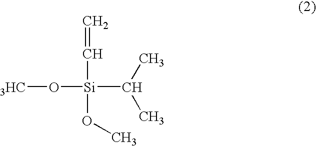

### EXAMPLES

For further detailed explanation of the above-described exemplary embodiment of the present invention, certain Examples of the present invention will now be described with reference to the drawings.

### Example 1

Example 1 of the present invention is now described with reference to FIGS. 4A to 4E.

FIG. 4A shows a substrate prepared using the standard method for fabricating an integrated circuit. The substrate is shown in the state a MIS FET 20 has been built thereon. In FIG. 4A, 1 is a substrate, 2 is an STI (shallow trench isolation), 3 is a gate insulating film and 4 is a gate electrode. In the present Example, a silicon substrate is used as the substrate.

Referring to FIG. 4A, dangling bonds of the gate insulating film of the MIS FET are terminated by heat treatment of 400° C. for 20 minutes, under the atmosphere of a hydrogen containing gas, thereby stabilizing the interface between the gate insulating film 3 and the substrate 1.

The insulating film 5 is then deposited on the entire substrate surface, by the CVD method, as shown in FIG. 4B.

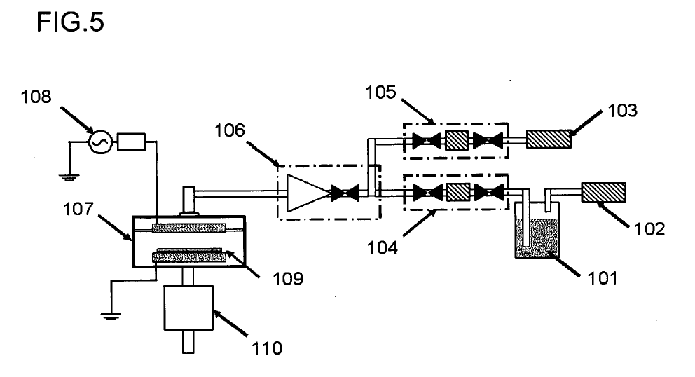

An apparatus for depositing the insulating film 5 is shown schematically in FIG. 5. A reservoir 101 is a vessel used for feeding a monomer raw material. A raw material pressure feed unit 102 pressurizes the raw material within the reservoir 101 to feed the raw material. As the pressurizing gas, He is used. A carrier gas feed unit 103 feeds He to transport the monomer raw material. A liquid mass flow controller 104 is a section for controlling the flow rate of the raw material. A gas mass flow controller 105 is a section for controlling the flow rate of He as a carrier gas. A vaporizer 106 is a device for vaporizing the monomer raw material, and a reactor 107 is a vessel in which the vaporized raw material is formed into a film by chemical vapor deposition.

An RF power supply 108 is a device for supplying the power used to turn the vaporized monomer raw material and the carrier gas into the state of plasma. A substrate 109 is a target on which is formed a film by chemical vapor deposition. An vacuum pump 110 is a device which exhausts the raw material gas and the carrier gas, introduced into the reactor 7, from the reactor 7.

The process for forming the insulating film 5, using the apparatus shown in FIG. 5, will now be described. The raw material is fed from the reservoir 101 by He gas from the raw material pressure feed unit 102, and has its flow rate controlled by the liquid mass flow 104. He gas is fed from the carrier gas feed unit 103 and has its flow rate controlled by the gas mass flow controller 105. The raw material and He, as the carrier gas, are mixed together directly ahead of the vaporizer 106 and introduced into the vaporizer 106. A heated heater block, not shown, is provided within the vaporizer 106. The liquid monomer raw material is vaporized there and introduced in the so vaporized state into the reactor 107. The monomer raw material, thus vaporized, and the carrier gas, are turned into plasma within the reactor 107 by the high frequency of 13.56 MHz. A high-modulus low-dielectric constant film is formed on the substrate 109 by chemical vapor deposition. The flow rate of the monomer raw material in the course of forming the high-modulus low-dielectric constant film is preferably 0.5 to 2 g/min. and more preferably 0.8 to 1.5 g/min. The flow rate of He, as the carrier gas, is preferably 100 to 1000 sccm and more preferably 200 to 500 sccm. The pressure within the reactor 107 is preferably 200 Pa to 533 Pa and more preferably 266 Pa to 400 Pa. The output power of the RF power supply is preferably 50 to 800 W and more preferably 100 to 500 W. By using the above-described film-forming process, the raw material monomer may be activated to perform sufficient movement on the substrate. The film forming is by the polymerization reaction of the polymerization cross-linking groups. This allows the insulating film 5 to be uniformly deposited on the substrate surface. The insulating film is also formed uniformly on the MIS FET, such that film forming may be achieved without forming voids between dense MIS FET patterns.

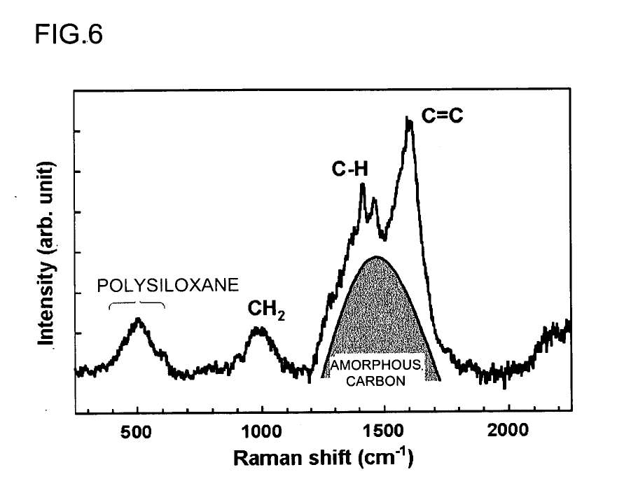

The results of Raman spectroscopic analysis of the high-modulus low-dielectric constant film, which has been formed by the above technique with the use of the monomer shown by the formula (2) as the raw material, are shown in FIG. 6. A broad peak, presumably ascribable to amorphous carbon, and peaks proper to double bond and to the hydrocarbon, may be noticed in a range from 1200 to 1700 cm⁻¹. The peaks proper to amorphous carbon are in the vicinity of 1400 cm⁻¹ and in the vicinity of 1600 cm⁻¹. In general, the peak in the vicinity of 1400 cm⁻¹ is taken as being proper to carbon of a sp² structure, while the peak in the vicinity of 1600 cm⁻¹ is taken as being proper to carbon of a sp³ structure. Thus, with the Raman spectroscopic analysis, it is possible to confirm that amorphous carbon and unsaturated hydrocarbons are contained in the high-modulus low-dielectric constant film obtained on film forming from the monomer of the formula (2) as the raw material.

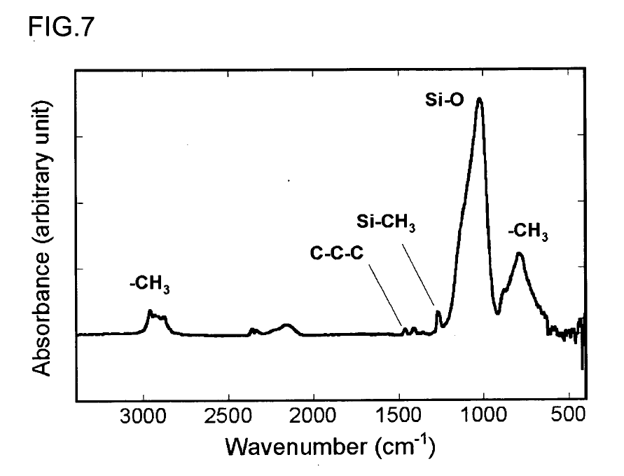

The absorption spectra by Fourier transform infrared spectroscopy (FT-IR) of the high-modulus low-dielectric constant film, obtained on film forming of the monomer of the formula (2) as the raw material, are shown in FIG. 7. There is a very strong peak, ascribable to Si—O in the vicinity of 1000 cm⁻¹, while there is a sharp peak, ascribable to S₁—CH₃, in the vicinity of 1250 cm⁻¹. There are rather strong peaks, ascribable to the methyl group, in the vicinity of 800 cm⁻¹ and in the vicinity of 2900 cm⁻¹. These absorption peaks are also confirmed with a common SiOCH film. On the other hand, the peak in the vicinity of 1465 cm⁻¹ is taken as an absorption peak ascribable to a C—C—C bond, and may be considered to be ascribable to the isopropyl group contained in the formula (2). This is scarcely confirmed with the common SiOCH film and is a characteristic absorption peak noticed in the high-modulus low-dielectric constant film made from the monomer of the formula (2) as a raw material.

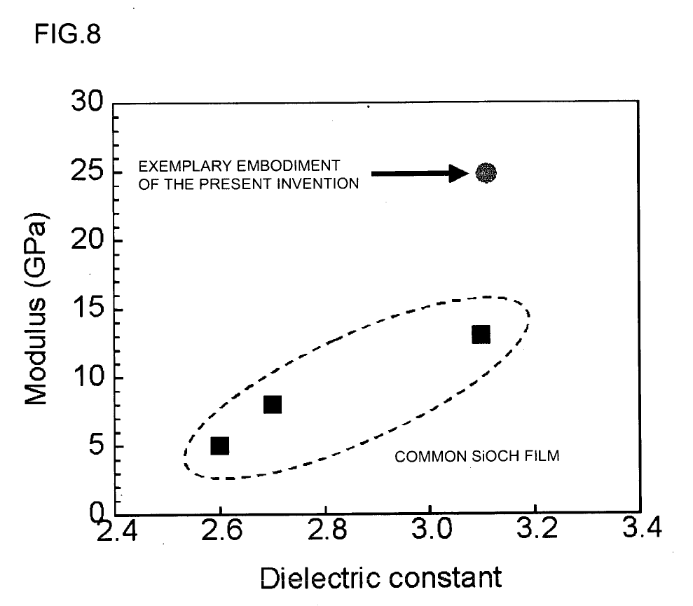

This film has a high modulus. FIG. 8 shows results of measurement of the modulus of a high-modulus low-dielectric constant film 500 nm in thickness by the nano-indentation method. The film has been formed by the above technique from the monomer of the formula (2) as a raw material. FIG. 8 also shows the modulus and a k-value of a common SiOCH film. It should be noted that the high-modulus low-dielectric constant film of the present exemplary embodiment has a film strength of 25 GPa which is appreciably higher than the film strength of ca. 5 to 15 GPa of the common SiOCH film.

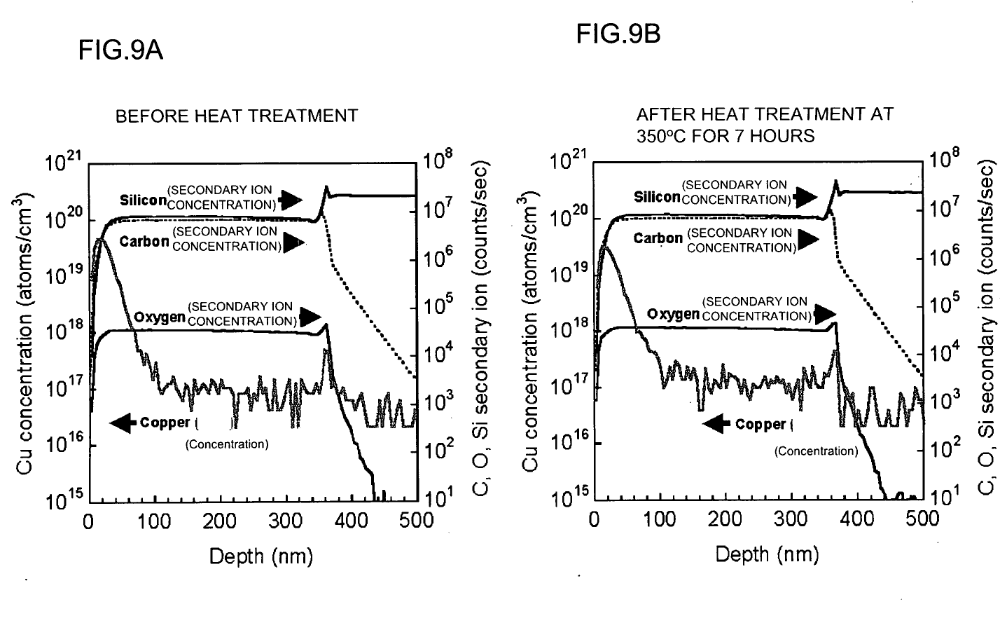

FIG. 9 shows resistance against Cu diffusion of the high-modulus low-dielectric constant film that has been formed by the above technique using the monomer of the formula (2) as the raw material. For evaluation, the high-modulus low-dielectric constant film was formed on a silicon substrate to 400 nm, plated with copper and heat-treated at 350° C. for seven hours, after which depth profile of Cu was measured by SIMS (Secondary Ion Mass Spectroscopy). For SIMS analysis, sputtering was carried out from the Si substrate surface to prevent injection of surface Cu by primary ions, and depth profile of Cu was investigated before and after heat treatment. FIG. 9A shows the profile in the depth-wise direction before heat treatment, and FIG. 9B shows the profile in the depth-wise direction after heat treatment. The results of the SIMS analysis indicated that there is no change in depth-wise Cu distribution before and after heat treatment, thus showing that the high-modulus low-dielectric constant film obtained on film forming from the monomer of the equation (1) as the raw material exhibits high resistance against Cu diffusion. The dielectric constant of the high-modulus low-dielectric constant film was 3.1.

Then, as shown in FIG. 4C, the insulating film 5 is planarized, and an opening 11 (contact hole or connection opening) is formed by lithography and etching.

A barrier layer 6 including tantalum (Ta) and a seed layer including copper (Cu) (not shown), are then formed in this order by sputtering on an inner wall of the opening 11, as shown in FIG. 4D. The electrically conductive member 7 of copper is then filled into the opening 11 by plating.

Finally, copper on the insulating film 5 is removed by the CMP technique so that the upper surface of the insulating film 5 will be flush with the upper surface of the electrically conductive member 7. This forms a contact plug, as shown in FIG. 4E, as, an electrically conductive member 8 filled into the opening 11 is left.

After that, multi-layer interconnects are formed to complete the semiconductor integrated circuit.

With the method for fabricating the semiconductor device of the present Example 1, the insulating film 5 exhibits resistance against Cu diffusion. Thus, when copper is used as the contact plug of the semiconductor device, it is possible to suppress copper from being diffused from a contact plug via the insulating film to the impurity diffusing region of the MIS FET. Moreover, since the insulating film 5 has a high mechanical strength and a low dielectric constant, the semiconductor device may be of low parasitic resistance and low parasitic capacitance and may be capable of performing a high-speed operation.

### Example 2

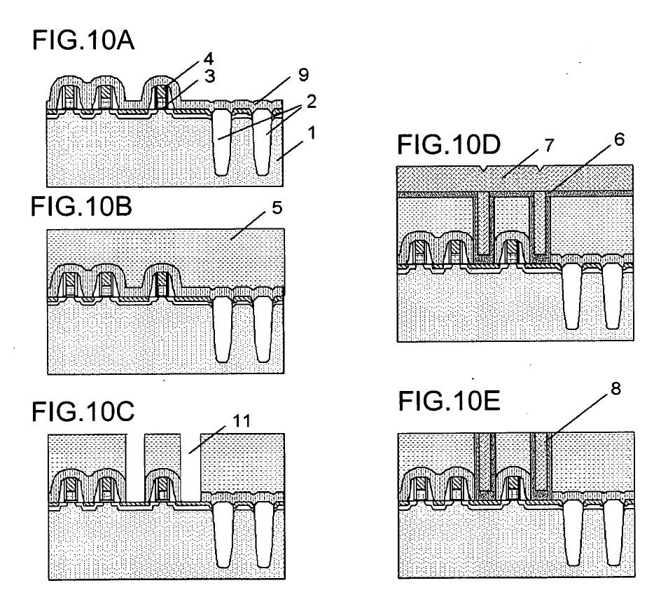

Example 2 of the present invention is now described with reference to FIGS. 10A to 10E.

FIG. 10A shows a substrate prepared using the standard method for fabricating an integrated circuit. The substrate is shown in the state a MIS FET 20 has been built thereon. In FIG. 10A, 1 is a substrate, 2 is a STI (shallow trench isolation), 3 is a gate insulating film, 4 is a gate electrode and 9 is a stress film. In the present Example, a silicon substrate is used as the substrate 1.

Referring to FIG. 10A, dangling bonds of the gate insulating film of the MIS FET are terminated by heat treatment of 400° C. for 20 minutes under the atmosphere of a hydrogen containing gas, thereby stabilizing the interface between the gate insulating film 3 and the substrate 1.

An insulating film 5 is then deposited on the entire substrate surface by the plasma CVD technique, in the same way as in Example 1, as shown in FIG. 10B.

The insulating film 5 is then planarized, as shown in FIG. 10C, and then an opening 11 (contact hole or connection opening) is formed by lithography and etching.

A barrier layer 6 including Ta (tantalum) and a seed layer including copper (not shown), are then formed in this order by sputtering on an inner wall of the opening 11, as shown in FIG. 10D. An electrically conductive member 7 of copper is then filled into the opening 11 by plating.

Finally, copper on the insulating film 5 is removed by the CMP technique so that the upper surface of the insulating film 5 will be flush with the upper surface of the electrically conductive member 7, such as to leave an electrically conductive member 8 filled into the opening 11, thus forming a contact plug, as shown in FIG. 4E.

After that, multi-layer interconnects are formed to complete the semiconductor integrated circuit.

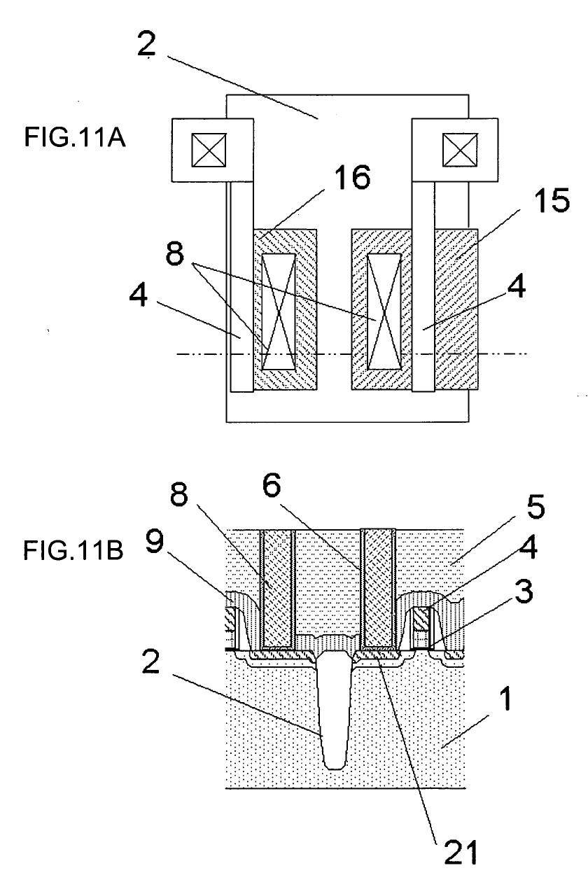

In the step of forming the opening 11 of the present Example, a contact for the impurity diffusing region 21 may be formed to a slit-like (that is, rectangular) shape as shown in FIGS. 11A and 11B. FIG. 11B is a cross-sectional view taken along the double-dotted chain line of FIG. 11A. With the contact part of the slit-like shape, the contact area of the contact plug with the insulating film 5 surrounding the contact plug is increased. Then, it becomes crucial for the insulating film 5, in particular a lowermost insulating film in case the insulating film is of a multi-layer structure, to exhibit resistance against copper diffusion. Since the cross-sectional area (contact area) of the contact plug is increased, the parasitic resistance may further be lowered.

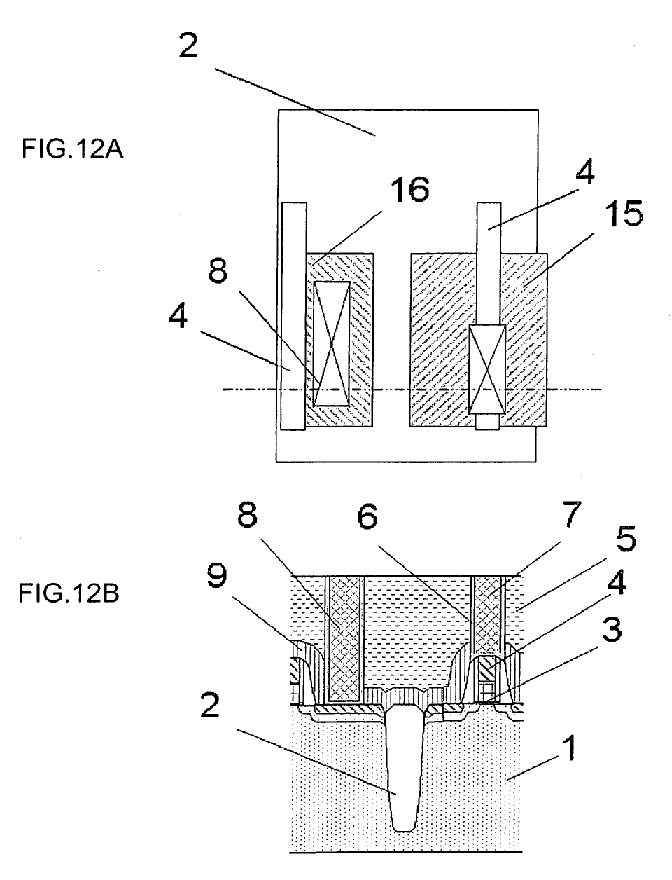

In the present Example, it is also possible to change the shape of the contact of the gate electrode 4 to a slit-like shape (rectangular shape) in the step of forming the opening 11, as shown in FIGS. 12A and 12B. FIG. 12B is a cross-sectional view of a portion shown by a double-dotted chain line of FIG. 12A. For further reducing the contact resistance with the gate electrode 4, a gate contact is provided on the gate electrode 4, and the contact shape is changed to a slit-like shape (rectangular shape). With the contact part of the slit-like shape, the contact area with the insulating film 5 surrounding the contact plug is increased. Then, it becomes crucial for the insulating film 5, in particular a lowermost insulating film in case the insulating film is of a multi-layer structure, to exhibit resistance against copper diffusion. Since the length of the gate electrode may substantially be discounted, it is possible to decrease the parasitic resistance of the gate electrode. Moreover, since the cross-sectional area (contact area) of the contact plug is increased, the parasitic resistance may further be lowered.

With the method for fabricating the semiconductor device of the present Example 2, the insulating film 5 exhibits resistance against copper diffusion. Thus, even in case a stress film is provided on top of the MIS FET, it is possible to suppress copper diffusion via the insulating film 5. In addition, such a semiconductor device may be provided which is low in parasitic resistance or parasitic capacitance and which enables a high speed operation.

### Example 3

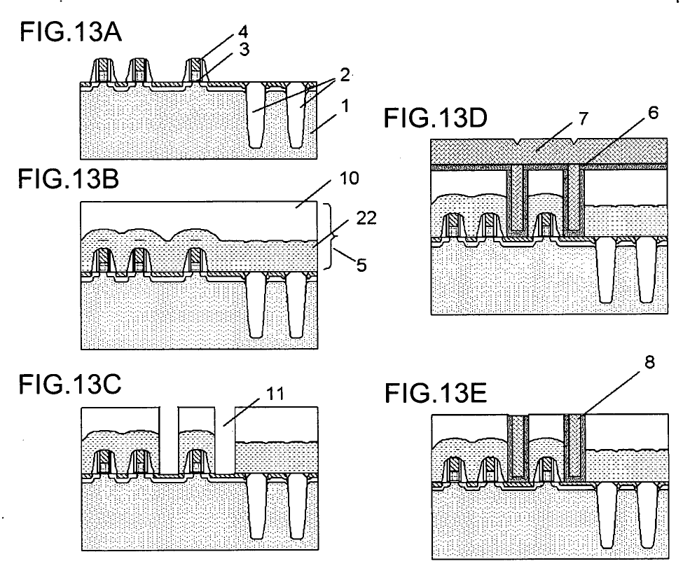

Example 3 of the present invention is now described with reference to FIGS. 13A to 13E.

FIG. 13A shows a substrate prepared using the standard method for fabricating an integrated circuit. The substrate is shown in the state a MIS FET 20 has been built thereon. In FIG. 13A, 1 is a substrate, 2 is a STI (shallow trench isolation), 3 is a gate insulating film and 4 is a gate electrode. In the present Example, a silicon substrate is used as the substrate.

Referring to FIG. 13A, dangling bonds of the gate insulating film of the MIS FET are terminated by heat treatment of 400° C. for 20 minutes under the atmosphere of a hydrogen containing gas for stabilizing the interface between the gate insulating film 3 and the substrate 1.

An insulating film 22 is then deposited on the entire substrate surface by the plasma CVD technique, in the same way as in Examples 1 and 2, as shown in FIG. 13B. An insulating film 10 is then deposited by a similar film-forming method, such as to cover the insulating film 22. Although the insulating film 10 is desirably of a low dielectric constant, with the dielectric constant being 3.5 or less, it may also be a silicon oxide film obtained by, for example, a plasma CVD technique. It is noted that, in the present Example, the insulating films 22 and 10, combined together, are equivalent to the insulating film 5 of Examples 1 and 2.

When the insulating film 10 is formed on the insulating film 22, surface processing may be carried out first to assure sufficient bonding performance, such as by feeding the He gas and applying the RF power, before proceeding to deposit the insulating film 10.

The insulating film 10 is then planarized, as shown in FIG. 13C, and an opening 11 (contact hole or connection opening) was formed by lithography and etching.

A barrier layer 6 including Ta and a seed layer including copper (not shown), were then formed in this order by sputtering on an inner wall of the opening 11, as shown in FIG. 13D. An electrically conductive member 7 of copper is then filled into the opening 11 by plating.

Finally, copper on the insulating film 10 is removed by the CMP technique so that the upper surface of the insulating film 10 will be flush with the upper surface of the electrically conductive member 7, such as to leave an electrically conductive member 8 filled into the opening 11, thus forming a contact plug, as shown in FIG. 4E.

After that, multi-layer interconnects are then formed to complete the semiconductor integrated circuit.

With the method for fabricating the semiconductor device of Example 3, the lowermost insulating layer 22 of the multi-layered insulating film on the MIS FET exhibits the resistance against copper diffusion. Thus, copper diffusion via the insulating layer 22 may be suppressed as in Examples 1 and 2. In addition, such a semiconductor device may be provided which is low in parasitic resistance or parasitic capacitance and which enables a high-speed operation.

### Example 4

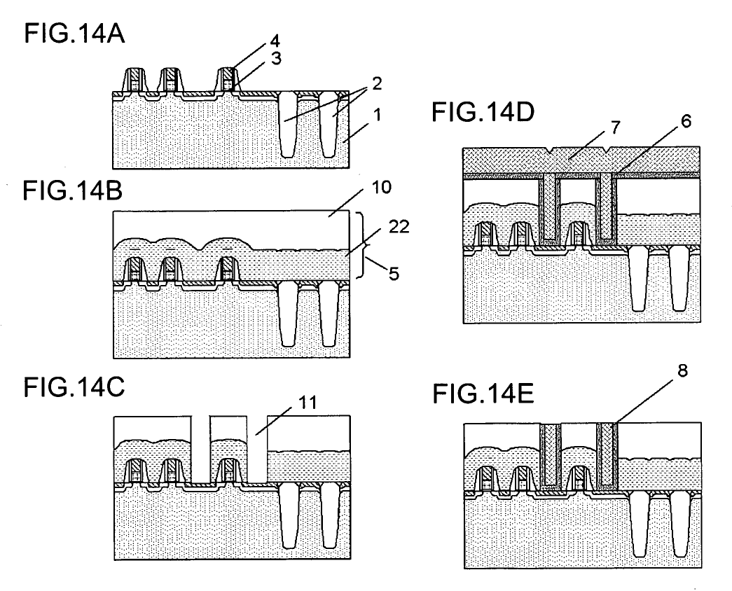

Example 4 of the present invention is now described with reference to FIG. 14A to 14E.

FIG. 14A shows a substrate prepared using the standard method for fabricating an integrated circuit. The substrate is shown in the state a MIS FET 20 has been built thereon. In FIG. 14A, 1 is a substrate, 2 is a STI (shallow trench isolation), 3 is a gate insulating film, 4 is a gate electrode and 9 is a stress film. In the present Example, a silicon substrate is used as the substrate.

Referring to FIG. 14A, dangling bonds of the gate insulating film of the MIS FET are terminated by heat treatment of 400° C. or 20 minutes under the atmosphere of a hydrogen containing gas for stabilizing the interface between the gate insulating film 3 and the substrate 1.

An insulating film 22 and an insulating film 10 are then deposited in this order on the entire substrate surface by the plasma CVD technique, in the same way as in Examples 3, as shown in FIG. 14B. It is noted that, in the present Example, the insulating films 22 and 10, combined together, are equivalent to the insulating film 5 of Examples 1 and 2.

The insulating film 10 is then planarized, as shown in FIG. 14C, and an opening 11 (contact hole or connection opening) is formed by lithography and etching.

A barrier layer 6 including Ta and a seed layer including copper (not shown) are then formed in this order by sputtering on an inner wall of the opening 11, as shown in FIG. 14D. The electrically conductive member 7 of copper is then filled into the opening 11 by plating.

Finally, copper on the insulating film 10 is removed by the CMP technique so that the upper surface of the insulating film 10 will be flush with the upper surface of the electrically conductive member 7, such as to leave an electrically conductive member 8 filled into the opening 11, thus forming a contact plug, as shown in FIG. 14E.

After that multi-layer interconnects are then formed to complete the semiconductor integrated circuit.

With the method for fabricating the semiconductor device of Example 4, the lowermost insulating layer 22 of the multi-layered insulating film on the MIS FET exhibits the resistance against copper diffusion. Thus, copper diffusion via the insulating layer 22 may be suppressed as in Examples 1 to 3, even in case a stress film is provided on the MIS FET. Thus, such a semiconductor device may be provided which is low in parasitic resistance or capacitance and which enables a high-speed operation.

### Example 5

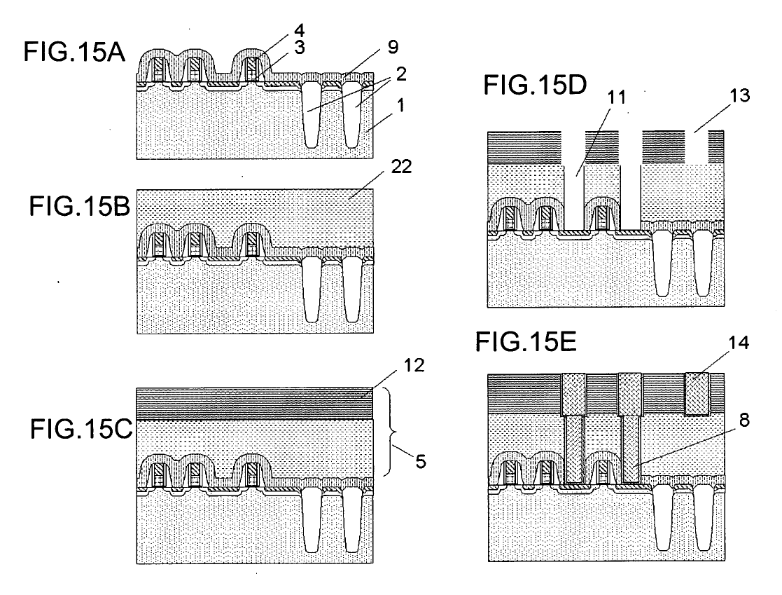

Example 5 of the present invention is now described with reference to FIGS. 15A to 15E.

FIG. 15A shows a substrate prepared using the standard method for fabricating an integrated circuit. The substrate is shown in the state a MIS FET 20 has been built thereon. In FIG. 15A, 1 is a substrate, 2 is a STI (shallow trench isolation), 3 is a gate insulating film, 4 is a gate electrode and 9 is a stress film. In the present Example, a silicon substrate is used as the substrate.

Referring to FIG. 15A, dangling bonds of the gate insulating film of the MIS FET are terminated by heat treatment of 400° C. for 20 minutes under the atmosphere of a hydrogen containing gas for stabilizing the interface between the gate insulating film 3 and the substrate 1.

An insulating film 22 is then deposited on the entire substrate surface by the plasma CVD technique, in the same way as in Examples 1 and 2, as shown in FIG. 15B.

An insulating film (conductor layer insulating film) 12 is then deposited to cover the insulating film 22 by a film forming method similar to that for forming the insulating film 22. The insulating film 12 is a low dielectric constant film with the dielectric constant preferably of not lower than 3.5 and more preferably not higher than 3.0. However, it may also be of a silicon oxide film obtained by, for example, plasma CVD. The insulating film 12 may also be of multi-layered structure of hetero layers, such as SiOC film and SiCN film. The multi-layered structure is not limited to a double layer structure but may also be three- or four-layer structure. In the present Example, the insulating films 22 and 12, combined together, are equivalent to the insulating layer 5 in Examples 1 and 2.

hen the insulating film 12 is formed on the insulating film 22, surface processing may be carried out first to assure sufficient bonding performance, such as by feeding a He gas and applying the RF power, before proceeding to deposit the insulating film 12.

The contact plug and the interconnect are simultaneously formed using the dual damascene technique. By the damascene conductor is meant a buried conductor formed by embedding a metal conductor precursor in a pre-formed groove of an insulating film and by removing excess metal other than the metal in the groove by CMP, for instance.

An opening 11 (contact hole or connection opening) is formed by lithography and etching, and an interconnect groove 13 is also formed, as shown in FIG. 15D.

Referring to FIG. 15E, a barrier layer 6 including Ta and a seed layer including copper (not shown,) are then formed in this order by sputtering on an inner wall surface of the opening 11 and the interconnect groove 13. The electrically conductive member 7 of copper is then filled into the opening 11 and into the interconnect groove 13 by plating. Finally, an excess portion of the barrier metal 6 and the electrically conductive member 7 is removed by the CMP technique so that the upper surface of the insulating film 12 will be flush with the upper surface of the electrically conductive member 7, such as to leave an electrically conductive member 8, thus forming a contact plug.

After that, multi-layer interconnects are formed to complete the semiconductor integrated circuit.

With the method for fabricating the semiconductor device of the present Example 5, copper diffusion via the insulating film 22 may be suppressed even in case the contact plug and the interconnect are formed simultaneously in accordance with the dual damascene technique. It is because the insulating film 22 on the MIS FET exhibits resistance against Cu diffusion. Also, the semiconductor device fabricated is low in parasitic resistance or parasitic capacitance, while being capable of a high speed operation, by the same reason as set forth in connection with Examples 1 to 4.

### Example 6

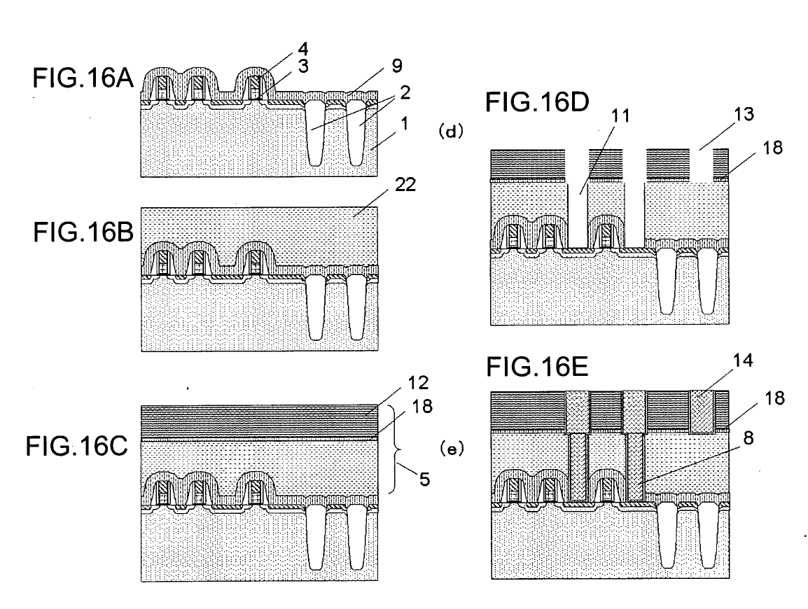

Example 6 of the present invention is now described with reference to FIGS. 16A to 16E.

FIG. 16A shows a substrate prepared using the standard method for fabricating an integrated circuit. The substrate is shown in the state a MIS FET 20 has been built thereon. In FIG. 16A, 1 is a substrate, 2 is a STI (shallow trench isolation), 3 is a gate insulating film, 4 is a gate electrode and 9 is a stress film. In the present Example, a silicon substrate is used as the substrate.

Referring to FIG. 16A, dangling bonds of the gate insulating film of the MIS FET are terminated by heat treatment of 400° C. for 20 minutes under the atmosphere of a hydrogen containing gas, thereby stabilizing the interface between the gate insulating film 3 and the substrate 1.

An insulating film 22 is then deposited on the entire substrate surface by the plasma CVD technique, in the same way as in Examples 1 and 2, as shown in FIG. 16B.

An etch stop film 18 and an insulating film (conductor layer insulating film) 12 are then deposited in this order to cover the insulating film 22, by a film forming method similar to that used for the insulating film 22. The insulating film 12 is a low dielectric constant film with a dielectric constant preferably not higher than 3.5 and more preferably not higher than 3.0. It may also be a silicon oxide film obtained by plasma CVD, for instance. The etch stop film 18 plays the role of a stopper to provide for an even depth of the interconnect groove 13 when the interconnect groove 13 is formed by dry etching the insulating film 12. It is thus preferred to dry etch the etch stop film at an etch rate lower than that for the insulating film 12. The etch rate ratio of the insulating film 12 with respect to the etch stop film 18 is 3:2, preferably 2:1 and more preferably higher than 2:1. It is thus preferred for the film density or the film composition of the etch stop film 18 to differ appreciably from that of the insulating film 12. For example, if nitrogen is not contained as a main component in the etch stop film 18, nitrogen is desirably contained in the etch stop film 18. If no carbon is contained in the insulating film 12, carbon is desirably contained in the etch stop film 18. If the same elements are contained in the etch stop film 18 and in the insulating film 12, it is preferred that the ratio of the contents of the elements of one of the two films differs appreciably from that of the other film. For example, the ratio of the contents of carbon or nitrogen of one of the two films is preferably thrice or more that of the other film. In the present Example, the insulating film 22, etch stop film 18 and the insulating film 12, combined together, are equivalent to the insulating film 5 in Examples 1 and 2.

The contact plug and the interconnect are formed simultaneously using the dual damascene technique. An opening 11 (contact hole or connection opening) is formed by lithography and etching, and an interconnect groove 13 is also formed, as shown in FIG. 16D.

Referring to FIG. 16E, a barrier layer 6 including Ta and a seed layer including copper (not shown), are then formed in this order by sputtering on an inner wall surface of an interconnect groove 13 and the opening 11. The electrically conductive member 7 of copper was then filled into the opening 11 and into the interconnect groove 13 by plating. Finally, an excess portion of the barrier metal 6 and the electrically conductive member 7 was removed by the CMP technique so that the upper surface of the insulating film 12 will be flush with the upper surface of the electrically conductive member 7 of copper, such as to leave an electrically conductive member 8, thus forming a contact plug and the interconnect 14.

After that, multi-layer interconnects are then formed to complete the semiconductor integrated circuit.

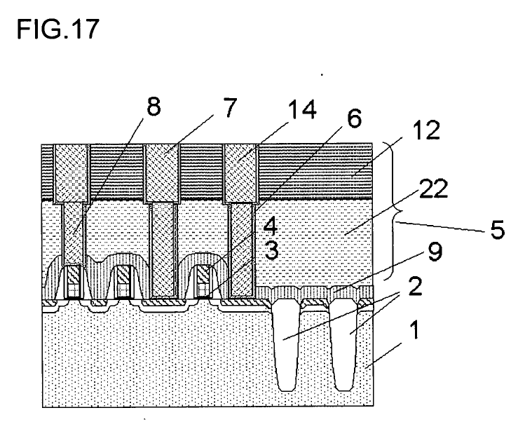

FIG. 17 shows an example in which, in the process step of FIG. 16D, the opening 11 (contact hole or connection opening) is formed by lithography and etching to get to the gate electrode 4 of the MIS FET. By this process step, the contact plug may be contacted directly on the top of the gate electrode 4.

With the method for fabricating the semiconductor device of the present Example 6, it is possible to suppress copper diffusion via the insulating film 22, as in the case of Example 5. In addition, such a semiconductor device may be provided which is low in parasitic resistance or parasitic capacitance and which enables a high speed operation.

### Example 7

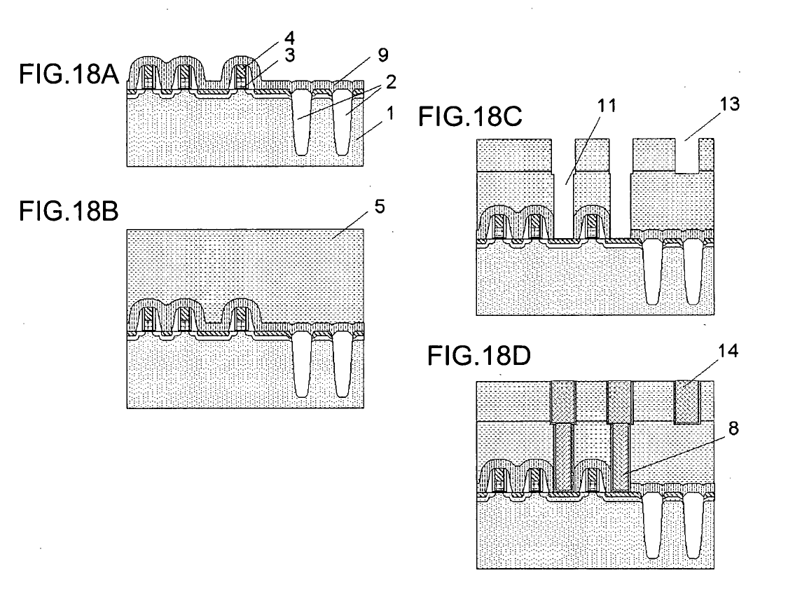

Example 7 of the present invention is now described with reference to FIGS. 18A to 18D.

FIG. 18A shows a substrate prepared using the standard method for fabricating an integrated circuit. The substrate is shown in the state a MIS FET 20 has been built thereon. In FIG. 18A, 1 is a substrate, 2 is a STI (shallow trench isolation), 3 is a gate insulating film, 4 is a gate electrode and 9 a stress film. In the present Example, a silicon substrate is used as the substrate 1.

Referring to FIG. 18A, dangling bonds of the gate insulating film of the MIS FET are terminated by heat treatment of 400° C. for 20 minutes under the atmosphere of a hydrogen containing gas to render the interface between the gate insulating film 3 and the substrate 1 stable.

Then, by the method similar to that used in connection with the Examples 1 and 2, an insulating film 5 is deposited on the entire substrate surface, by the plasma CVD method, to a film thickness corresponding to the combined thicknesses of the insulating films 22 and 12 in the Examples 5 and 6.

An opening 11 (contact hole or connection opening) is formed by lithography and etching, and an interconnect groove 13 is also formed, as shown in FIG. 18C.

Referring to FIG. 18D, a barrier layer 6 including Ta and a seed layer including copper (not shown), were then formed in this order by sputtering on an inner wall surfaces of the interconnect groove 13 and the opening 11. The electrically conductive member 7 of copper was then filled into the opening 11 and into the interconnect groove 13 by plating. Finally, an excess portion of the barrier metal 6 and the electrically conductive member 7 was removed by the CMP technique, so that the upper surface of the insulating film 12 will be flush with the upper surface of the electrically conductive member 7, such as to leave an electrically conductive member 8, thus forming a contact plug and a conductor 14.

After that, a multi-layer interconnects are then formed to complete the semiconductor integrated circuit.

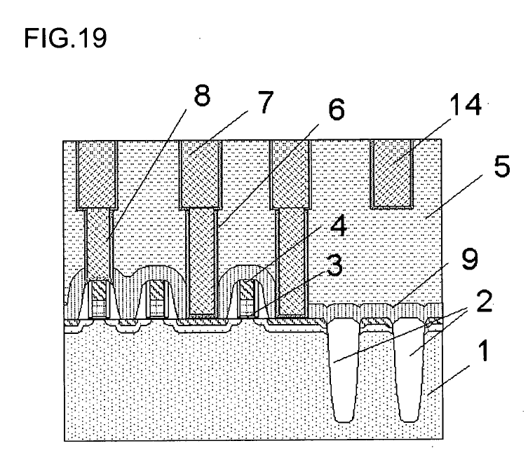

FIG. 19 shows an example in which, in the process step of FIG. 18C, the opening 11 (contact hole or connection opening) was formed to get to the gate electrode of the MIS FET by lithograph and etching. This process step may yield a configuration in which the contact plug is directly contacted with the gate electrode 4.

With the method for fabricating the semiconductor device of the present Example 7, it becomes possible to suppress copper diffusion via the insulating film 5, as in the case of Examples 5 and 6. Such a semiconductor device may be provided which is low in parasitic resistance or capacitance and which enables a high speed operation.

### Example 8

Example 8 of the present invention is now described with reference to FIGS. 3A and 3B.

In the process step of forming the opening 11 of Example 2, the opening 11 is formed to get to both the impurity diffusing region 21 and the gate electrode 4 of the MIS FET 20. A semiconductor integrated circuit was completed with the other process steps unchanged from Example 2.

FIG. 3B depicts a cross-sectional view taken along a double-dotted chain line of FIG. 3A. If, in a circuit of, for example, a SRAM (Static Random Access Memory), it is desired to miniaturize the circuit area, a common contact shaped as shown in FIGS. 3A and 3B is formed as a local conductor to interconnect the gate and the source drain area with the shortest distance. Since the contact is rectangular in shape, the contact area with the insulating film surrounding the contact plug is increased. It is thus crucial that the interlayer insulating film, in particular the lowermost interlayer dielectric film in the case of a multi-layered structure, exhibits resistance against copper diffusion. The term ‘rectangular shape’ as used herein denotes not only the inherent rectangular shape but also the shape of a rectangle with rounded corners. It is noted that the winding grooves 13 of Examples 5 to 7 are not shown.

With the method for fabricating a semiconductor device of the present Example 8, since the insulating film 5 exhibits resistance against Cu diffusion, such a semiconductor device may be provided in which, if copper is used as a contact plug of the semiconductor device, it is possible to suppress copper diffusion from the contact plug via the insulating film to the impurity diffusing region of the MIS FET.

### Example 9

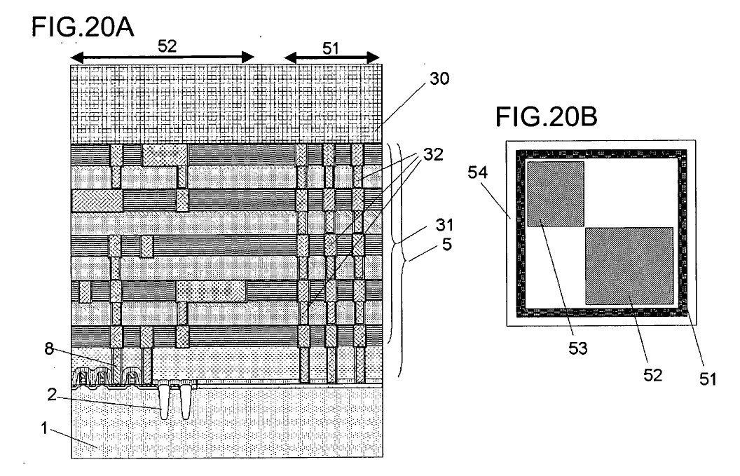

Example 9 of the present invention is now described with reference to FIGS. 20A and 20B.

A semiconductor integrated circuit is fabricated, in the same way as in Example 2, using a substrate prepared using the standard method for fabricating an integrated circuit. The substrate used has a MIS FET 20 built thereon. At this time, a set of slit conductors 32, including, as a main component, copper, while provided for surrounding the MIS FET, as shown in FIG. 20A. The set of slit conductors 32 is configured to form a metal wall section extending from the surface of the insulating film 5 to the substrate 1. The set of slit conductors 32 was formed in the same way as contact plugs, via plugs or conductors were formed in the integrated circuit forming area 52. A passivation film 30 was provided as an uppermost layer of the integrated circuit forming area 52 where a multi-layer interconnect has been formed. FIG. 20B depicts an idealized top plan view of FIG. 20A.

Referring to FIGS. 20A and 20B, the integrated circuit forming area 52 is surrounded by a seal ring area 51 including the slit conductor set 32. Although the number of the slit conductors of the slit conductor set shown in FIG. 20A is three, it may also be two or four. The slit conductor set 32 may be formed around the integrated circuit forming area 52 by a single turn, however, it is preferably formed around the integrated circuit forming area by two or more folds. A plurality of integrated circuit forming areas may be provided in the seal ring area. For example, an integrated circuit forming area 53 may also be provided in the seal ring area. It is however preferred that integrated circuit forming areas in a silicon chip 54, where integrated circuits are formed, are all provided within the seal ring area 51.

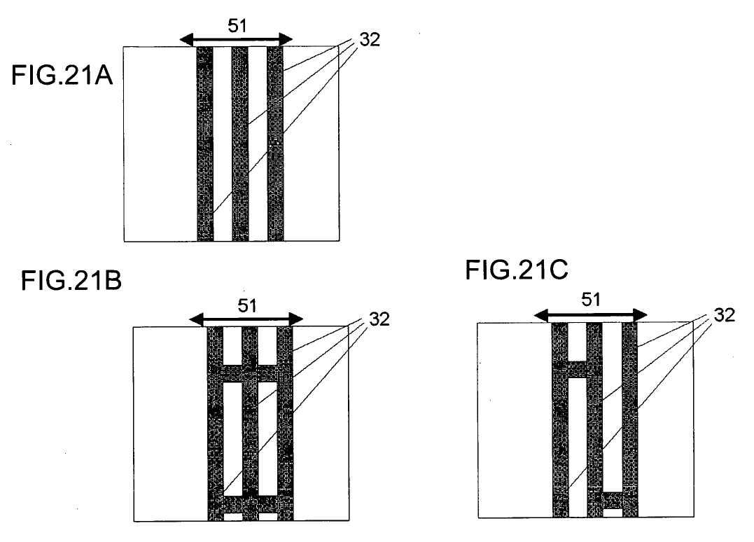

The slit conductor set 32, when seen from its top side, may be in the shape of a simple ring, as shown in FIG. 21A. When seen from the top side, the slit conductor set may also be in the shape of a lattice as shown in FIG. 21B, or may be in the shape of a lattice with cross-pieces of the lattice structure in a staggered pattern, as shown in FIG. 21C. Although FIGS. 21A-21C show three slit conductors of the conductor set 32, it is preferably formed with two or more slit conductors, as previously mentioned.

As described above, the metal wall section is provided for surrounding the integrated circuit forming area formed on the semiconductor substrate. The metal wall section is formed for passing through the insulating film surrounding the contact plug to get to the silicon substrate. By so doing, it becomes possible to prevent moisture contained in air from intruding from the lateral side of the insulating film into the integrated circuit forming area in the course of assembling the silicon chip into e.g. a resin mold. The silicon chip, thus assembled, has an integrated circuit built thereon and has been cut from a silicon wafer. If moisture is present in the insulating film, copper is ionized by electron exchange with water during copper diffusion in the insulating film. It is therefore crucial not to allow for intrusion of moisture into the insulating film. With the metal wall section, surrounding the integrated circuit, as described above, the probability of occurrence of failures in integrated circuits may be decreased to improve the useful life and reliability of the integrated circuit appreciably.

### Example 10

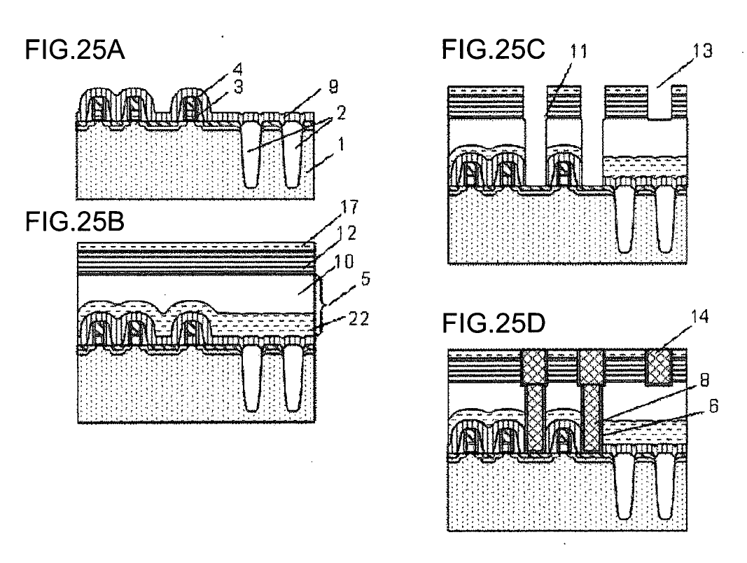

Example 10 of the present invention is now described with reference to FIGS. 25A to 25D.

FIG. 25A shows a substrate prepared using the standard method for fabricating an integrated circuit. The substrate is shown in the state a MIS FET 20 has been built thereon. In FIG. 25A, 1 is a substrate, 2 is a STI (shallow trench isolation), 3 is a gate insulating film, 4 is a gate electrode and 9 a stress film. In the present Example, a silicon substrate is used as the substrate 1.

In FIG. 25A, heat treatment may be carried out at 400° C. for 20 minutes in a hydrogen gas containing atmosphere. This terminates dangling bonds of the gate insulating film of the MIS FET to render the interface between the gate insulating film 3 and the substrate 1 stable. If it is known from the outset that there are scarcely any dangling bonds such that a stable interface has been formed, the heat treatment may be dispensed with.

An insulating film 22 and an insulating film 10 are then deposited on the entire substrate surface by the plasma CVD technique, in the same way as in Example 1, as shown in FIG. 25B. In the present Example, the insulating films 22 and 10, combined together, are equivalent to the insulating layer 5 in Example 1.

The insulating film 10 is then planarized in the same way as in Example 1. An insulating film (conductor layer insulating film) 12 is then deposited to cover the insulating film 5 by a film forming method similar to that used for forming the insulating film 22. A hard mask film 17 is then similarly deposited on the insulating film 12. The insulating film 12 and the hard mask insulating film 17 are low dielectric constant films with the dielectric constant not higher than 3.5 and preferably not higher than 3.0. However, they may also be silicon oxide films obtained by e.g. plasma CVD.

If used for working the insulating film 12, the hard mask film 17 is preferably higher in film density or in mechanical strength, such as Young's modulus, than the insulating film 12. The hard mask film 17 may also be a multi-layered structure composed of a plurality of insulating layers. Or, the hard mask film 17 may also be deposited simultaneously during formation of the insulating film 12 such as by changing the film forming condition or changing the film-forming material. The insulating film 12 may also be a multi-layered structure composed of hetero layers, such as SiOC film and a SiCN film.

A contact plug and a conductor were then formed simultaneously, using the dual damascene technique. That is, an opening 11 (contact hole or connection opening) was formed by lithography and etching, and an interconnect groove 13 was also formed, as shown in FIG. 25C.

A barrier layer 6 including stacked films of Ta/TaN, and the seed layer including copper (not shown), are then formed in this order by sputtering on an inner wall surface of the interconnect groove 13 and the opening 11. An electrically conductive member 7 of copper was then filled into the opening 11 and into the interconnect groove 13 by plating. Finally, an excess portion of the barrier metal 6 and the electrically conductive member 7 was removed by the CMP technique so that the upper surface of the insulating film 12 will be flush with the upper surface of the electrically conductive member of copper, such as to leave an electrically conductive member 8, thus forming a contact plug and a conductor 14.

After that, a multi-layer interconnects are then formed to complete the semiconductor integrated circuit.

With the method for fabricating the semiconductor device of Example 10, copper diffusion via the insulating film 22 may be suppressed, as in Example 6. In addition, such a semiconductor device may be fabricated in which parasitic resistance or parasitic capacitance is low and which enables a high speed operation.

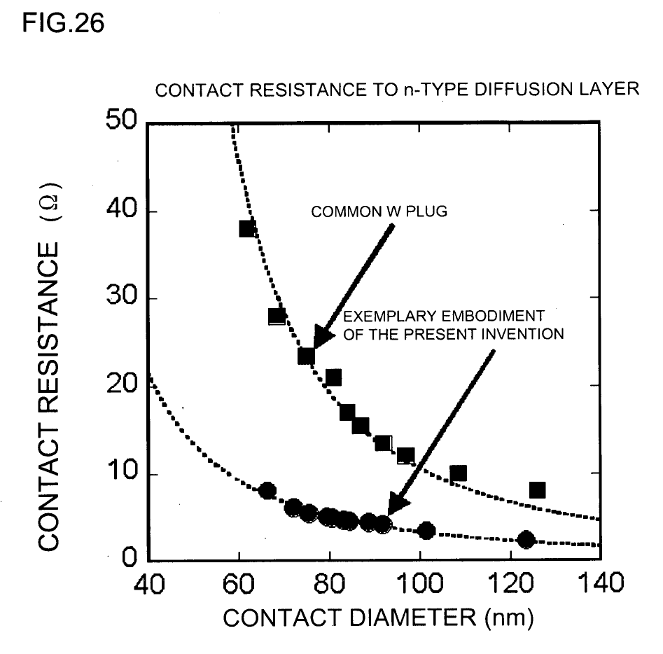

FIG. 26 shows measured results of the resistance value of the contact plug obtained with the method for fabricating the semiconductor device of Example 10 and the resistance value of a routine W (tungsten) plug. It is seen that the contact resistance has been appreciably decreased with the method of the present Example. With the contact diameter of, for example, 75 nm, the resistance value, which was 23.5Ω with the use of the W plug, could be reduced to 5.4Ω.

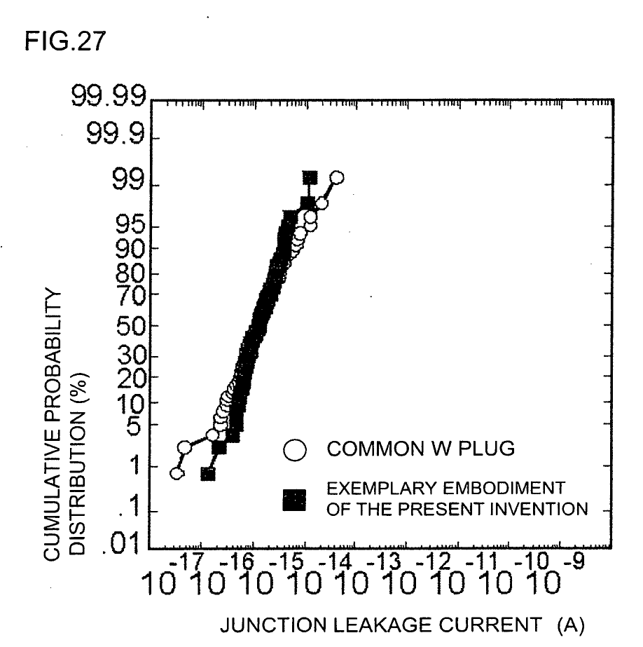

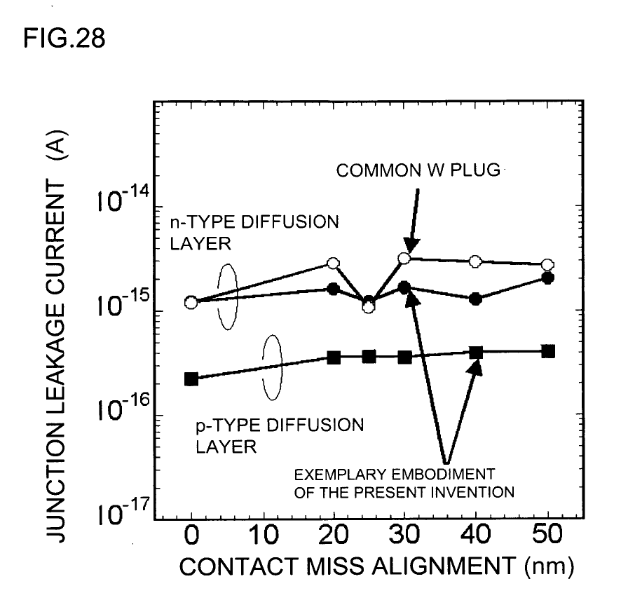

The results of comparison of the junction leakage current characteristic in case of forming a contact plug obtained with the method for fabricating the semiconductor device of Example 10 on a n-type impurity diffusion region with that with the common W (tungsten) plug are shown in FIG. 27. The junction leakage current characteristic in case the position of registration is willfully shifted in forming a contact plug by the method of the present Example 10 to a n-type or p-type impurity diffusing region is shown in FIG. 28. It is seen that, with both of these characteristics, the leakage current values compare favorably with those with the W plug. When Cu silicide is formed or, if things do not go so far, but Cu is diffused, the leakage current is felt to be increased. Hence, the above results presumably indicate that copper may be prevented from being diffused from the contact plug used in the present Example.

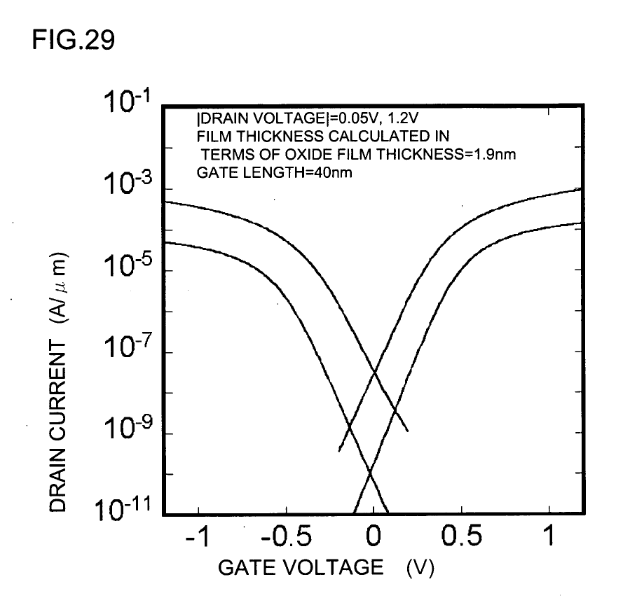

FIG. 29 shows measured results of the relationship between the gate voltage and the drain current in a transistor employing the contact plug obtained by the method for fabricating the semiconductor device of Example 10. It is seen that an unobjectionable characteristic, which in no way is different from the transistor characteristic employing well-known W plugs, has been realized. If copper has happened to be diffused to the vicinity of the transistor from the contact plug of copper used in the present Example, a knee would appear in the characteristic shown in FIG. 29, or a characteristic curve would be distorted.

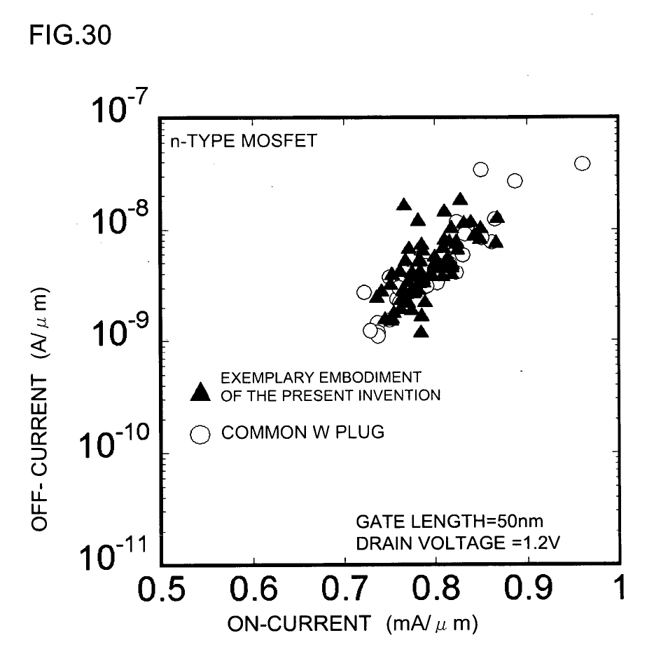

FIG. 30 shows measured results of the relationship between the on-current and the off-current in a transistor employing the contact plug obtained by the method for fabricating the semiconductor device of Example 10. It is seen that the characteristic thus measured is approximately the same as that of the transistor employing the routine W plug. It may be confirmed that the transistor characteristic is not deteriorated with the method of the present Example.

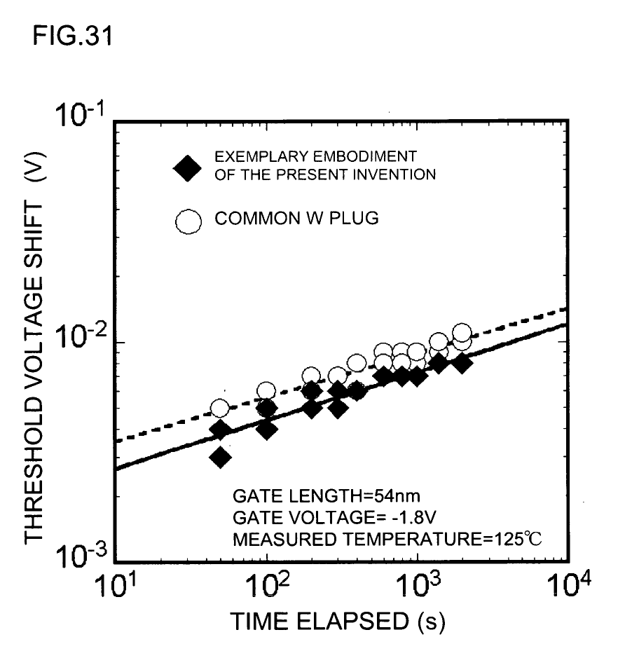

FIG. 31 shows results of evaluation of NBTI (Negative Bias Temperature Instability) in a transistor employing a contact plug obtained with the method for fabricating the semiconductor device of Example 10. It is seen that the results indicate a characteristic similar to that of a transistor employing a common W plug. It may be confirmed that the initial stage reliability of a transistor obtained with the method for fabricating the semiconductor device of Example 10 is equivalent to that of a transistor employing the well-known W plug.

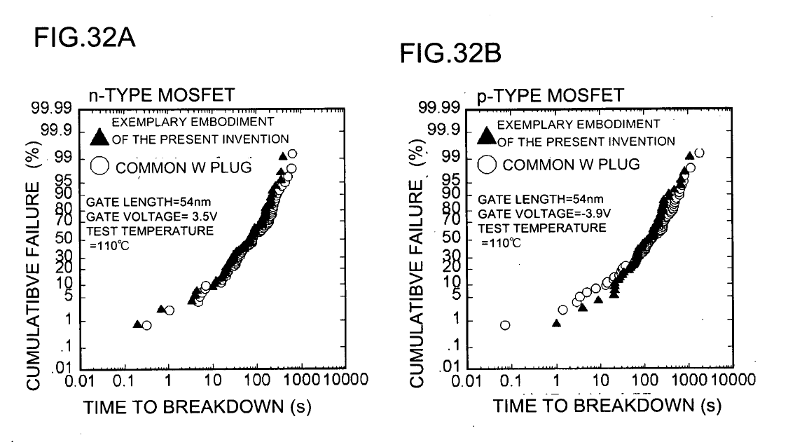

FIGS. 32A and 32B show the results of a TDDB (Time Dependent Dielectric Breakdown) test as a reliability evaluation of a gate insulating film of a transistor obtained with Example 10 and that of a transistor employing a well-known W plug. FIG. 32A shows the results for a n-type MOSFET, and FIG. 32B those for a p-type MOSFET. It is seen that, for both of these transistors, the useful life of the gate insulating film for the case of the inventive method is about equal to that for the case of using the W plug. It is therefore possible with the technique of the present Example to prevent Cu from being diffused through the bulk of the insulating film, to avoid deterioration of the transistor characteristic, and to secure reliability equivalent to that of the conventional process.

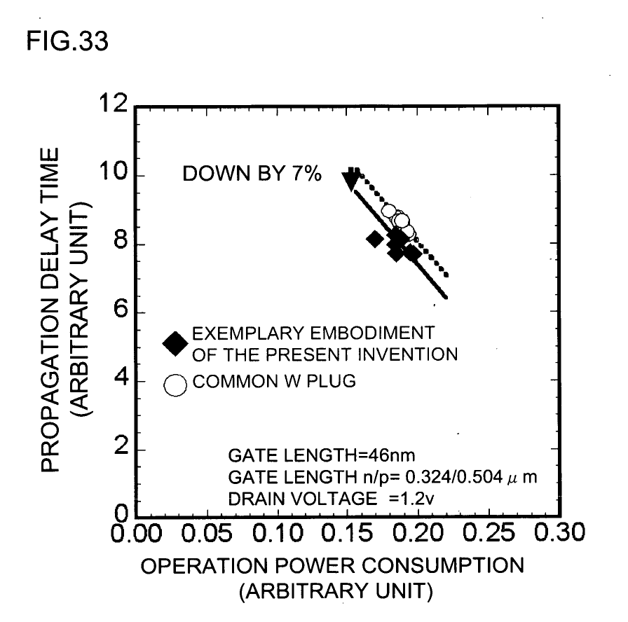

FIG. 33 shows the results of comparison of the gate delay time and the power consumption of a ring oscillator formed by a transistor obtained with Example 10 and that formed by a transistor employing a common W plug. It is seen that the dielectric constant of the insulating film surrounding the contact plug has been decreased with the technique of the present Example. Hence, approximately 7% reduction in signal delay has been obtained with the ring oscillator obtained with the present technique as compared that obtained with the ring conventional oscillator, with the power consumption of the two ring oscillators being the same. Thus, by reducing the dielectric constant of the insulating film surrounding the contact plug, it is possible to improve the operating speed without detracting from transistor reliability.

The disclosures of the above Patent Documents are to be incorporated herein by reference. Although the present invention has so far been described with reference to preferred exemplary embodiments and Examples, the present invention is not to be restricted to these embodiments or Examples. It is to be appreciated that those skilled in the art can change or modify the embodiments or Examples without departing from the spirit and the scope of the present invention.

1. A semiconductor device comprising:
a substrate;
a MIS FET provided on a surface of the substrate;
an insulating film provided on the substrate to cover the MIS FET;
an opening formed in the insulating film, the opening getting to an impurity diffusing region of the MIS FET;
another opening formed in the insulating film, the another opening getting to a gate electrode of the MIS FET or to an extension part of the gate electrode; and
an electrically conductive member filled into each of the openings, the electrically conductive member including, as a main component, copper;
the insulating film including a layer comprising, as main components, silicon, oxygen, carbon and hydrogen.

2. The semiconductor device according to claim 1, wherein the insulating film has a multi-layered structure, at least one layer of the multi-layered structure including, as main components, silicon, oxygen, carbon and hydrogen.

3. The semiconductor device according to claim 1, wherein the insulating film has a multi-layered structure; at least the lowermost layer of the multi-layered structure including, as main components, silicon, oxygen, carbon and hydrogen.

4. The semiconductor device according to claim 1, wherein the insulating film includes an opening getting to a region astride the impurity diffusing region and the gate electrode of the MIS FET.

5. The semiconductor device according to claim 1, wherein the openings get to the impurity diffusing region and to the gate electrode or the extension part of the gate electrode of the MIS FET from an interconnect arranged in the insulating film.

6. The semiconductor device according to claim 1, wherein a barrier layer is provided on an inner wall of the opening.

7. The semiconductor device according to claim 1, wherein the layer comprising, as main components, silicon, oxygen, carbon and hydrogen, includes amorphous carbon and unsaturated hydrocarbons.

8. The semiconductor device according to claim 7, wherein the amorphous carbon includes an atom of sp² hybrid orbitals and an atom of sp³ hybrid orbitals.

9. The semiconductor device according to claim 1, wherein the insulating film has a metal wall getting to the substrate from the surface of the insulating film to surround the MIS FET.

10. A method for fabricating a semiconductor device comprising:
(a) depositing an insulating film including, as main components, silicon, oxygen, carbon and hydrogen, on a substrate on which a MIS FET is provided, so as to cover the MIS FET;
(b) forming, in the insulating film, an opening getting to an impurity diffusing region of the MIS FET and another opening getting to a gate electrode of the MIS FET or an extension part of the gate electrode;
(c) depositing a barrier layer and a seed layer in this order on an inner wall of the opening;
(d) filling an electrically conductive member including, as a main component, copper, in each of the openings; and
(e) removing the electrically conductive member on the insulating film so that an upper surface of the insulating film will be flush with an upper surface of the electrically conductive member.

11. A method for fabricating a semiconductor device comprising:
(a) depositing an insulating film including, as main components, silicon, oxygen, carbon and hydrogen, on a semiconductor substrate oil which a MIS FET is provided, so as to cover the MIS FET;
(a′) forming an interconnect layer insulating film on the insulating layer;
(b) forming, in the insulating film and in the interconnect layer insulating film, an opening getting to an impurity diffusing region of the MIS FET and another opening getting to a gate electrode or to an extension part of the gate electrode;
(c) depositing a barrier layer and a seed layer in this order on an inner wall of the opening;
(d) filling an electrically conductive member including, as a main component, copper, in each of the openings; and
(e) removing the electrically conductive member on the interconnect layer insulating film so that an upper surface of the interconnect layer insulating film will be flush with an upper surface of the electrically conductive member in the opening.

12. The method according to claim 10, wherein in depositing the insulating film, the deposition is carried out by a plasma chemical vapor deposition method.

13. The method according to claim 10, wherein in depositing the insulating film, helium is used as a carrier gas.

14. The method according to claim 10, wherein in depositing the insulating film, a compound represented by the following formula (1) is used a raw material, 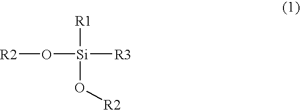
wherein R1 is any one of a vinyl group, a propenyl group and an isopropenyl group;
R2 is any one of a methyl group, an ethyl group, a propyl group, an isopropyl group and an isobutyl group; and
R3 is any one of a methyl group, an ethyl group, a propyl group, an isopropyl group and an isobutyl group.

15. The method for fabricating a semiconductor device according to claim 14, wherein the compound is isopropyl dimethoxyvinyl siloxane represented by the following formula (2).

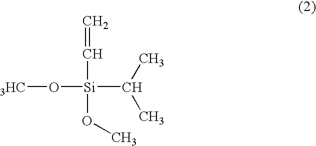

16. The semiconductor device according to claim 1, wherein a gate insulating film between the substrate and the gate electrode in the MIS FET has a single-layer structure or a multi-layered structure.

17. The semiconductor device according to claim 1, wherein the extension part of the gate electrode is arranged at a position along the width-wise direction of the gate electrode; and wherein
the gate electrode is extended along the gate width direction beyond the impurity diffusing region to get to the extension part of the gate electrode.

18. The method according to claim 10, wherein a gate insulating film between the substrate and the gate electrode in the MIS FET has a single-layer structure or a multi-layered structure.

19. The method according to claim 10, wherein the extension part of the gate electrode is arranged at a position along the width-wise direction of the gate electrode in a spaced-apart relationship with respect to the impurity diffusing region; and wherein
the gate electrode is extended along the gate width direction beyond the impurity diffusing region to get to the extension part of the gate electrode.

20. The semiconductor device according to claim 1, wherein, in the insulating film,
the layer including, as main components, Si (silicon)-O (oxygen)-C (carbon)-H (hydrogen) includes
Si:O:C:H with a composition ratio equal to 1.0:1.5:1.0:4.0,
O, C and H, out of the four elements, being in a range of approximately 20% from the composition ratio, respectively.

21. The semiconductor device according to claim 9, comprising
two or more folds of the metal walls extending from the surface of the insulating film to the substrate,
the two or more folds of the metal walls having, as a shape seen from the upper surface of the substrate, at least one of:
a ring shape spaced apart from each other;
a lattice shape; and
a shape in which a plurality of cross-pieces arranged in a staggered relationship between two neighboring metal wall, the cross-pieces interconnecting the neighboring metal walls.

22. The semiconductor device according to clam 1, wherein a metal compound is formed on a surface of the impurity diffusing region and on a surface of the gate electrode.

23. The semiconductor device according to claim 1, wherein the gate electrode has a surface metalized and a portion on the gate insulating film thereof metalized.

24. The semiconductor device according to clam 1, wherein a contact of the opening on top of the impurity diffusing region has a slit shape.

25. The semiconductor device according to claim 1, wherein a contact of the opening on top of the gate electrode has a slit shape extended along the gate width direction.

26. The method according to claim 10, wherein,
in the insulating film, the layer including, as main components, Si (silicon)-O (oxygen)-C (carbon)-H (hydrogen) includes
Si:O:C:H with a composition ratio equal to 1.0:1.5:1.0:4.0,
O, C and H, out of the four elements, being in a range of approximately 20% from the composition ratio, respectively.
